(19) United States
(12) Patent Application Publication
(10) Pub. No.: US 2026/0198063 A1
(43) Pub. Date: Jul. 9, 2026

(54) POWER SEMICONDUCTOR DEVICES HAVING INTERSECTING GATE TRENCHES AND SUPPORT SHIELDS

(71) Applicant: Wolfspeed, Inc., Durham, NC (US)

(72) Inventors: Naeem Islam, Fuquay-Varina, NC (US); Woongsun Kim, Cary, NC (US); Ping-Ju Chuang, Morrisville, NC (US); Sei-Hyung Ryu, Cary, NC (US)

(21) Appl. No.: 19/013,026

(22) Filed: Jan. 8, 2025

(51) Int. Cl. H10D 64/27; H10D 30/66; H10D 62/10; H10D 64/00; H10D 84/83

(52) U.S. Cl. CPC H10D 64/519; H10D 62/107; H10D 64/117; H10D 84/839; H10D 30/668

(57) ABSTRACT

A semiconductor device comprises a semiconductor layer structure comprising a drift region having a first conductivity type, a plurality of continuous first gate trenches in the semiconductor layer structure, and a plurality of second gate trenches in the semiconductor layer structure, the second gate trenches intersecting the first gate trenches.

### FIELD OF THE INVENTION

The present invention relates to power semiconductor devices and, more particularly, to gate-controlled power semiconductor devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region that each have a first conductivity type are formed in the semiconductor layer structure and are separated from each other by a channel region that has a second conductivity type. A gate electrode is disposed adjacent the channel region and separated from the channel region by a thin dielectric layer. A MOSFET may be turned on or off by setting a bias voltage that is applied to the gate electrode to be above or below a threshold value (which may be a negative voltage). When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when the gate bias voltage that is applied to the gate electrode is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type conductivity, where the first and second conductivity types are different. Thus, if a first region of a device has a first conductivity type and a second region of the device has a second conductivity type, this means either that the first region has n-type conductivity and the second region has p-type conductivity or, alternatively, that the first region has p-type conductivity and the second region has n-type conductivity.

Because the gate electrode of a MOSFET is insulated from the channel region by the gate dielectric layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT.

In many applications, MOSFETs may need to carry large currents and/or be capable of blocking high voltages (e.g., hundreds or thousands of volts of electric potential). Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power MOSFETs and other power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

MOSFETs can have a lateral structure or a vertical structure. In a MOSFET having a lateral structure, the drain, gate and source terminals are on the same major surface (i.e., top or bottom) of a semiconductor layer structure. In contrast, in a device having a vertical structure, at least one terminal is provided on each major surface of the semiconductor layer structure (e.g., the source and gate may be on the top surface of the semiconductor layer structure and the drain may be on the bottom surface of the semiconductor layer structure).

The semiconductor layer structure of a power semiconductor device includes an “active region” in which one or more functional semiconductor devices are formed. The active region acts as a main junction for blocking voltage during reverse bias (off-state) operation and for providing current flow during forward bias (on-state) operation. The power semiconductor device may also have an edge termination structure such as guard rings and/or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the processed wafer may be diced to separate the individual edge-terminated power semiconductor devices. Each power semiconductor device may have a unit cell structure in which the active region includes a plurality of individual “unit cell” devices that are electrically connected in parallel and that together function as a single power semiconductor device.

Vertical gate-controlled power semiconductor devices can have a planar gate electrode design in which the gate electrodes are formed on top of the semiconductor layer structure or, alternatively, may have the gate electrodes formed within gate trenches in the semiconductor layer structure, which are typically referred to as gate trench devices. With the planar gate electrode design, the channel region of each unit cell transistor is horizontally disposed underneath the gate electrode. In contrast, in gate trench devices, the channels are typically vertically disposed adjacent sidewalls of the gate electrodes.

One failure mechanism for a power MOSFET is the so-called “breakdown” of the gate oxide layer. The gate oxide layer is subjected to high electric fields during normal device operation. The high electric fields degrade the gate oxide layer over time, and may eventually result in failure of the device. When gate trench MOSFETs operate in reverse blocking operation (i.e., when the MOSFET is in its off-state), the source terminal of the MOSFET is typically grounded, the gate terminal is typically grounded or at a negative bias voltage, and the drain terminal is typically at a high positive voltage. During such reverse blocking operations, strong electric fields extend upwardly from the drain terminal (which is on the lower surface of the semiconductor layer structure) toward the upper surface of the semiconductor layer structure. Thus, under reverse blocking operation, the portions of the gate oxide layers lining the bottoms of the gate trenches experience the highest electric field levels. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source region, thereby creating a short-circuit that can destroy the device. The “lifetime” of a gate oxide layer (i.e., how long the device can be operated before breakdown occurs) is a function of, among other things, the magnitudes of the electric fields that the gate oxide layer is subjected to and the length of time for which the electric field is applied. Generally speaking, the relationship between the magnitude of the applied electric field and gate oxide lifetime may be generally linear when the gate oxide lifetime is plotted on a logarithmic scale, meaning that as the electric field level is increased, the lifetime of the gate oxide layer decreases exponentially.

The “pitch” of a semiconductor device having a unit cell structure refers to the center-to-center distance between adjacent unit cells. As the pitch is decreased (meaning the unit cells are packed closer together), the integration level of a semiconductor device increases, which is desirable. Vertical gate-controlled power semiconductor devices such as power MOSFETs and IGBTs that have a gate trench design have a smaller pitch than comparable planar gate-controlled vertical power semiconductor devices. The increased degree of integration provided by the reduced pitch lowers the on-state resistance per unit area. Moreover, vertical power semiconductor devices that have a gate trench design exhibit increased carrier mobility (2-4 times higher) than comparable planar gate vertical power semiconductor devices, which acts to further reduce the on-state resistance. However, as discussed above, gate trench power MOSFETs are susceptible to oxide reliability issues due to the presence of high electric fields in the gate oxide layers, with the lower “corners” of the gate oxide layers at the bottom edges of the gate trenches being experiencing particularly high electric fields.

So-called “trench shields” (also called “bottom shields”) are often provided underneath the gate trenches of gate trench power MOSFETs and/or support shields may be provided in between adjacent gate trenches in order to reduce the electric field levels in the bottom portions of the gate oxide layers during reverse blocking operation. FIGS. 1A and 1B illustrate a small portion of a gate trench power MOSFET 1 that includes both trench shields and support shields. In particular, FIG. 1A is a schematic plan view of the conventional gate trench power MOSFET 1, while FIG. 1B is a cross-sectional view taken along line 1B-1B of FIG. 1A. In FIG. 1A, the upper metallization and dielectric layers are omitted to show the gate electrodes and the upper surface of the semiconductor layer structure, while in FIG. 1B the upper metallization and dielectric layers are added to provide context.

As shown in FIG. 1A, power MOSFET 1 includes a wide bandgap semiconductor layer structure 60 that comprises a plurality of silicon carbide layers. The semiconductor layer structure 60 has first and second major surfaces that each extend in the x-direction and the y-direction of an x-y-z coordinate system. The semiconductor layer structure 60 has a thickness in the z-direction, which is also referred to herein as the depth direction. The MOSFET 1 includes a large number of gate trenches 80 that are formed in the upper surface of the semiconductor layer structure 60. Only two gate trenches 80 are shown in FIG. 1A, as FIG. 1A only illustrates a small representative section of power MOSFET 1. Each gate trench 80 has a longitudinal axis that extends in the x-direction so that the gate trenches 80 extend in parallel to each other.

Referring to FIG. 1B, the semiconductor layer structure 60 includes a thick heavily-doped n-type silicon carbide semiconductor substrate 10. A lightly-doped n-type (n⁻) silicon carbide drift region 20 (also referred to as a “drift layer”) is provided on the upper surface of the substrate 10. An upper portion of the drift region 20 may be more heavily doped than the remainder of the drift region 20, and this more highly-doped portion 22 of the drift region 20 is referred to herein as a JFET region 22 (which may be a continuous region or a plurality of discontinuous regions, as shown). A plurality of moderately-doped p-type wells 30 (also referred to as “p-wells”) are formed on the JFET regions 22, typically by ion implantation. The source regions 40 are formed on upper portions of the p-wells 30, typically by ion implantation. The gate trenches 80 extend downwardly through upper portions of the semiconductor layer structure 60 into the drift region 20. Moderately-doped p-type trench shields regions 50 are formed below each gate trench 80, and each trench shields 50 may extend substantially the length of its associated gate trench 80. Moderately-doped or heavily-doped p-type support shields 52 are formed in the upper surface of the semiconductor layer structure 60 in between each pair of adjacent gate trenches 80. A gate oxide layer 70 is formed conformally within each gate trench 80, and gate electrodes 82 are formed in the respective gate trenches 80 on the gate oxide layers 70. An intermetal dielectric pattern 72 covers the gate electrodes 82. A source metallization 90 is formed on the intermetal dielectric pattern 72 and on the n-type source regions 40 and the p-type support shields 52. The upper portion of each p-type support shield 52 may act as a well contact region that electrically connects the p-wells 30 to the source metallization 90. A metal drain contact 6 is formed on the lower surface of the substrate 10. The portion of each p-well 30 that is adjacent a gate oxide layer 70 acts as a channel region 32 through which the source-drain current flows during on-state operation.

The trench shields 50 and the support shields 52 are typically formed by ion implantation. The support shields 52 may be directly connected to the source metallization 90. The trench shields50 are electrically connected to the source metallization 90 by p-type trench shield connection patterns that are not visible in the views of FIGS. 1A-1B. The p-type trench shields 50 and support shields 52 act to suppress the electric fields in the upper portion of the semiconductor layer structure 60 during reverse blocking operation, thereby lowering the electric fields in the gate oxide layers 70, which improves the reliability of power MOSFET 1.

So-called “JFET gaps” 24 are defined in the semiconductor layer structure 60 between each support shield 52 and an adjacent trench shield 50. The on-state current flows through the JFET gaps 24 as the on-state current does not flow in the p-type trench shields 50 or in the p-type support shields 52. Current funneling may occur in the JFET gaps 24, which may increase the on-state resistance of power MOSFET 1. Additionally, the provision of the support shields 52 increases the “pitch” of power MOSFET 1′ (i.e., the distance between adjacent unit cells in the y-direction), since the pitch must be increased to make room for the support shields 52. The increased pitch (and hence reduced degree of integration) also acts to increase the on-state resistance per unit area.

### SUMMARY

Pursuant to some embodiments of the present invention, semiconductor device are provided that comprise a semiconductor layer structure comprising a drift region having a first conductivity type, a plurality of continuous first gate trenches in the semiconductor layer structure, and a plurality of second gate trenches in the semiconductor layer structure, the second gate trenches intersecting the first gate trenches.

In some embodiments, the semiconductor device further comprises a gate dielectric layer and a gate electrode in each of the first gate trenches and in each of the second gate trenches.

In some embodiments, the first gate trenches extend in parallel to each other and each first gate trench has a longitudinal axis that extends in a first direction. In some embodiments, the first gate trenches and the second gate trenches are in an upper surface of the semiconductor layer structure, and each first gate trench has a zig-zag shape when viewed from above. In some embodiments, the first and second gate trenches define a plurality of parallelogram-shaped mesas in the semiconductor layer structure. In other embodiments, the first and second gate trenches define a plurality of isosceles trapezoid-shaped regions in the semiconductor layer structure.

In some embodiments, the semiconductor layer structure further comprises a plurality of first support shields that have the second conductivity type, the first support shields having respective third longitudinal axes that extend in the first direction in parallel to each other. In some embodiments, the first gate trenches, the second gate trenches and the first support shields together define a plurality of trapezoid-shaped regions in the semiconductor layer structure, where each trapezoid-shaped region has two right angles.

In some embodiments, the semiconductor layer structure further comprises a plurality of first support shields that have the second conductivity type, the first support shields having respective third longitudinal axes that extend in the first direction in parallel to each other. In some embodiments, the second gate trenches each have respective longitudinal axes that extend in a second direction in parallel to each other, where the second direction is different from the first direction. In some embodiments, the second direction is perpendicular to the first direction. In some embodiments, the semiconductor layer structure further comprises a plurality of second support shields that have the second conductivity type, the second support shields having respective fourth longitudinal axes that extend in the second direction in parallel to each other. In some embodiments, the second gate trenches are discontinuous gate trenches that each comprise a plurality of colinear spaced apart segments. In some embodiments, the first support shields are continuous first support shields. In some embodiments, the first support shields are discontinuous first support shields. In some embodiments, the second gate trenches are continuous gate trenches. In some embodiments, the first support shields are continuous first support shields. In some embodiments, the first support shields are discontinuous first support shields.

In some embodiments, the second support shields contact the first gate trenches.

In some embodiments, at least some of the second support shields are spaced-apart from the first gate trenches.

In some embodiments, a first spacing between adjacent ones of the first gate trenches is different than a second spacing between adjacent ones of the second gate trenches. In some embodiments, each first gate trench has a first width and each second gate trench has a second width that is different than the first width. In some embodiments, each first gate trench has a first depth into the semiconductor layer structure and each second gate trench has a second depth into the semiconductor layer structure that is different than the first depth.

Pursuant to further embodiments of the present invention, semiconductor device are provided that comprise a semiconductor layer structure comprising a drift region having a first conductivity type, a plurality of parallel first gate trenches in the semiconductor layer structure that have respective first longitudinal axes that extend in a first direction, a plurality of parallel second gate trenches in the semiconductor layer structure that have respective second longitudinal axes that extend in a second direction that intersects the first direction, a plurality of parallel first support shields that have the second conductivity type in the semiconductor layer structure that have respective third longitudinal axes that extend in the first direction, and a plurality of parallel second support shields that have the second conductivity type in the semiconductor layer structure that have respective fourth longitudinal axes that extend in the second direction.

In some embodiments, the first gate trenches are continuous gate trenches and the second gate trenches are discontinuous gate trenches. In some embodiments, the first support shields are continuous support shields and the second support shields are discontinuous support shields.

In some embodiments, the first support shields are continuous support shields and the second support shields are discontinuous support shields.

In some embodiments, the first gate trenches are discontinuous gate trenches and the second gate trenches are discontinuous gate trenches. In some embodiments, each segment of the discontinuous first gate trenches intersects a respective segment of the discontinuous second gate trenches to form a plurality if cross-shaped gate trench sections when the semiconductor device is viewed from above. In some embodiments, the first gate trenches are continuous gate trenches and the second gate trenches are continuous gate trenches. In some embodiments, the first support shields are continuous support shields. In some embodiments, second support shields are continuous support shields. In some embodiments, the second support shields are discontinuous support shields.

In some embodiments, the first support shields are discontinuous support shields and the second support shields are discontinuous support shields. In some embodiments, each segment of the discontinuous first support shields intersects a respective segment of the discontinuous second support shields to form a plurality of cross-shaped support shields sections when the semiconductor device is viewed from above.

In some embodiments, a first spacing between adjacent ones of the first gate trenches is different than a second spacing between adjacent ones of the second gate trenches. In some embodiments, each first gate trench has a first width and each second gate trench has a second width that is different than the first width. In some embodiments, each first gate trench has a first depth into the semiconductor layer structure and each second gate trench has a second depth into the semiconductor layer structure that is different than the first depth.

Pursuant to still further embodiments of the present invention, semiconductor device are provided that comprise a semiconductor layer structure comprising a drift region having a first conductivity type, a plurality of parallel continuous first gate trenches in the semiconductor layer structure that have respective first longitudinal axes that extend in a first direction, a plurality of parallel discontinuous second gate trenches in the semiconductor layer structure that have respective second longitudinal axes that extend in a second direction that intersects the first direction, where each discontinuous second gate trench comprises a plurality of colinear spaced apart segments, and a plurality of parallel first support shields that have the second conductivity type in the semiconductor layer structure that have respective third longitudinal axes that extend in the first direction.

In some embodiments, the semiconductor device further comprises a plurality of parallel second support shields that have the second conductivity type in the semiconductor layer structure that have respective fourth longitudinal axes that extend in the second direction. In some embodiments, the first support shields are continuous support shields. In some embodiments, the second support shields are discontinuous support shields. In some embodiments, a respective end of at least some of the segments of the second gate trenches abut the continuous first support shields.

In some embodiments, a respective end of at least some of the segments of the second gate trenches are spaced apart from the continuous first support shields and channel regions are defined in between the ends of the segments of the second gate trenches and the continuous first support shields. In some embodiments, ends of segments of the second support shields abut the continuous first gate trenches. In some embodiments, ends of segments of the second support shields are spaced apart from the continuous first gate trenches and channel regions are defined in between the ends of the segments of the second support shields and the continuous first gate trenches.

In some embodiments, a first spacing between adjacent ones of the first gate trenches is different than a second spacing between adjacent ones of the second gate trenches.

In some embodiments, each first gate trench has a first width and each second gate trench has a second width that is different than the first width.

In some embodiments, each first gate trench has a first depth into the semiconductor layer structure and each second gate trench has a second depth into the semiconductor layer structure that is different than the first depth.

Pursuant to other embodiments of the present invention, semiconductor device are provided that comprise a semiconductor layer structure comprising a drift region having a first conductivity type, a plurality of parallel first gate trenches in the semiconductor layer structure that have respective first longitudinal axes that extend in a first direction, a plurality of parallel second gate trenches in the semiconductor layer structure that have respective second longitudinal axes that extend in a second direction that is perpendicular to the first direction so that the first gate trenches and the second gate trenches form a gate trench mesh that defines a plurality of mesas in the semiconductor layer structure, and a plurality of first support shields in the semiconductor layer structure that have the second conductivity type.

In some embodiments, support shields are at least partially within the mesas.

In some embodiments, the gate trench mesh is a continuous gate trench mesh. In some embodiments, each first support shield comprises a continuous first support shield.

In some embodiments, the semiconductor device further comprises a plurality of second support shields in the semiconductor layer structure that have the second conductivity type. In some embodiments, the second support shields comprise continuous second support shields. In some embodiments, the second support shields comprise discontinuous second support shields that comprise a plurality of spaced apart segments. In some embodiments, at least one end of at least some of the segments of the second support shields abut the gate trench mesh. In some embodiments, at least one end of at least some of the segments of the second support shields are spaced apart from the gate trench mesh.

In some embodiments, a first spacing between adjacent ones of the first gate trenches is different than a second spacing between adjacent ones of the second gate trenches.

In some embodiments, each first gate trench has a first width and each second gate trench has a second width that is different than the first width.

In some embodiments, each first gate trench has a first depth into the semiconductor layer structure and each second gate trench has a second depth into the semiconductor layer structure that is different than the first depth.

Pursuant to additional embodiments of the present invention, semiconductor device are provided that comprise a semiconductor layer structure comprising a drift region having a first conductivity type, a first gate trench in the semiconductor layer structure that has alternating first segments and second segments, where first longitudinal axes of the first segments each extend in a first direction and second longitudinal axes of the second segments each extend in a second direction that intersects the first direction and a second gate trench in the semiconductor layer structure that intersects the first gate trench.

In some embodiments, the second gate trench intersects the first gate trench at a location where one of the first segments merges into one of the second segments.

In some embodiments, the second gate trench extends along a third longitudinal axis, and the first longitudinal axis of a first of the first segments and the third longitudinal axis define a first angle, and the second longitudinal axis of a first of the second segments and the third longitudinal axis define a second angle, where the second angle has the same absolute value as the first angle.

In some embodiments, the first gate trench has a zig-zag shape when viewed from above.

In some embodiments, the semiconductor device further comprises a first support shield in the semiconductor layer structure that has a second conductivity type, the first support shield having a fourth longitudinal axis that extends in parallel to the third longitudinal axis. In some embodiments, the semiconductor device further comprises a second support shield in the semiconductor layer structure that has a second conductivity type, the second support shield having a fifth longitudinal axis that extends perpendicularly to the third longitudinal axis.

In some embodiments, a first spacing between adjacent ones of the first gate trenches is different than a second spacing between adjacent ones of the second gate trenches. In some embodiments, each first gate trench has a first width and each second gate trench has a second width that is different than the first width. In some embodiments, each first gate trench has a first depth into the semiconductor layer structure and each second gate trench has a second depth into the semiconductor layer structure that is different than the first depth.

Pursuant to yet additional embodiments of the present invention, semiconductor device are provided that comprise a semiconductor layer structure comprising a drift region having a first conductivity type a first gate trench in the semiconductor layer structure that has a first longitudinal axis that extends in a first direction, a second gate trench in the semiconductor layer structure that has a zig-zag shape when viewed from above.

In some embodiments, the semiconductor device further comprises a third gate trench in the semiconductor layer structure that has a zig-zag shape when viewed from above. In some embodiments, the semiconductor device further comprises a first support shield in the semiconductor layer structure that has a second conductivity type.

In some embodiments, the first support shield is in between the second gate trench and the third gate trench when the semiconductor device is viewed from above.

In some embodiments, the semiconductor device further comprises a fourth gate trench in the semiconductor layer structure that has a second longitudinal axis that extends in the first direction. In some embodiments, the semiconductor device further comprises a second support shield in the semiconductor layer structure that has a second conductivity type, wherein the second support shield is in between the first gate trench and the fourth gate trench when the semiconductor device is viewed from above.

In some embodiments, the first gate trench, the second gate trench, the fourth gate trench and the first support shield together define a trapezoid-shaped region in the semiconductor layer structure that has two right angles. In some embodiments, the semiconductor device further comprises a fourth gate trench in the semiconductor layer structure that has a second longitudinal axis that extends in the first direction. In some embodiments, the first through fourth gate trenches define a parallelogram-shaped mesa in the semiconductor layer structure. In some embodiments, the first through fourth gate trenches define an isosceles trapezoid-shaped mesa in the semiconductor layer structure.

### BRIEF DESCRIPTION OF THE DRAWINGS

FIG. 1A is a schematic plan view of a small portion of a conventional gate trench power MOSFET with the upper metallization and dielectric layers omitted.

FIG. 1B is a cross-sectional view taken along line 1B-1B of FIG. 1A with the upper metallization and dielectric layers included.

FIG. 2A is a schematic top view of a gate trench silicon carbide power MOSFET according to certain embodiments of the present invention.

FIG. 2B is a schematic top view of the power MOSFET of FIG. 2A with an upper protective layer omitted to show the full gate and source metallization.

FIG. 3A is a schematic perspective view of a small portion of a power MOSFET according to embodiments of the present invention that corresponds to the box labelled A in FIG. 2A.

FIG. 3B is a schematic top view of the power MOSFET of FIG. 3A with the upper dielectric layers and the source metallization omitted to show the gate electrodes and the upper surface of the semiconductor layer structure.

FIGS. 3C-3F are cross-sectional views taken along lines 3C-3C, 3D-3D, 3E-3E and 3F-3F, respectively, of FIG. 3B with the upper dielectric layers and the source metallization that are omitted in FIG. 3B added for context.

FIG. 3G is a schematic top view of a modified version of the power MOSFET of FIG. 3A with the upper dielectric layers and the source metallization omitted to show the gate electrodes and the upper surface of the semiconductor layer structure.

FIG. 4A is a schematic top view of a small portion of a power MOSFET according to further embodiments of the present invention that corresponds to the box labelled A in FIG. 2A with the upper dielectric layers and the source metallization omitted to show the gate electrodes and the upper surface of the semiconductor layer structure.

FIG. 4B is a schematic top view of a modified version of the power MOSFET of FIG. 4A with the upper dielectric layers and the source metallization omitted to show the gate electrodes and the upper surface of the semiconductor layer structure.

FIG. 5A is a schematic top view of a small portion of a power MOSFET according to additional embodiments of the present invention that corresponds to the box labelled A in FIG. 2A with the upper dielectric layers and the source metallization omitted to show the gate electrodes and the upper surface of the semiconductor layer structure.

FIGS. 5B-5E are cross-sectional views taken along lines 5B-5B, 5C-5C, 5D 5D, and 5E-5E, respectively, of FIG. 5A with the upper dielectric layers and the source metallization that are omitted in FIG. 5A added for context.

FIG. 6A is a schematic top view of a power MOSFET according to yet additional embodiments of the present invention that corresponds to the box labelled A in FIG. 2A with the upper dielectric layers and the source metallization omitted to show the gate electrodes and the upper surface of the semiconductor layer structure.

FIG. 6B is a schematic top view of a modified version of the power MOSFET of FIG. 6A with the upper dielectric layers and the source metallization omitted to show the gate electrodes and the upper surface of the semiconductor layer structure.

FIG. 7A is a schematic top view of yet another power MOSFET according to embodiments of the present invention with the upper dielectric layers and the source metallization omitted to show the gate electrodes and the upper surface of the semiconductor layer structure.

FIGS. 7B and 7C are cross-sectional views taken along lines 7B-7B and 7C-7C of FIG. 7A, respectively, with the upper dielectric layers and the source metallization that are omitted in FIG. 7A added for context.

FIG. 7D is a schematic top view of a modified version of the power MOSFET of FIG. 7A with the upper dielectric layers and the source metallization omitted to show the gate electrodes and the upper surface of the semiconductor layer structure.

FIG. 8A is a schematic top view of still another power MOSFET according to embodiments of the present invention with the upper dielectric layers and the source metallization omitted to show the gate electrodes and the upper surface of the semiconductor layer structure.

FIGS. 8B and 8C are cross-sectional views taken along lines 8B-8B and 8C-8C of FIG. 8A, respectively, with the upper dielectric layers and the source metallization that are omitted in FIG. 8A added for context.

FIG. 8D is a schematic top view of a modified version of the power MOSFET of FIGS. 8A-8C with the upper dielectric layers and the source metallization omitted to show the gate electrodes and the upper surface of the semiconductor layer structure.

FIG. 9A is a schematic top view of a power MOSFET according to still further embodiments of the present invention that includes gate trenches that have a zig-zag pattern with the upper dielectric layers and the source metallization omitted to show the gate electrodes and the upper surface of the semiconductor layer structure.

FIGS. 9B-9D are cross-sectional views taken along lines 9B-9B, 9C-9C and 9D-9D of FIG. 9A, respectively, with the upper dielectric layers and the source metallization that are omitted in FIG. 9A added for context.

FIG. 10 is a schematic top view of a modified version of the power MOSFET of FIGS. 9A-9D with the upper dielectric layers and the source metallization omitted to show the gate electrodes and the upper surface of the semiconductor layer structure.

FIG. 11 is a schematic top view of a power MOSFET according to still further embodiments of the present invention that has gate trenches that follow a different zig-zag pattern with the upper dielectric layers and the source metallization omitted to show the gate electrodes and the upper surface of the semiconductor layer structure.

FIG. 12 is a schematic top view of a modified version of the power MOSFET of FIG. 11 with the upper dielectric layers and the source metallization omitted to show the gate electrodes and the upper surface of the semiconductor layer structure.

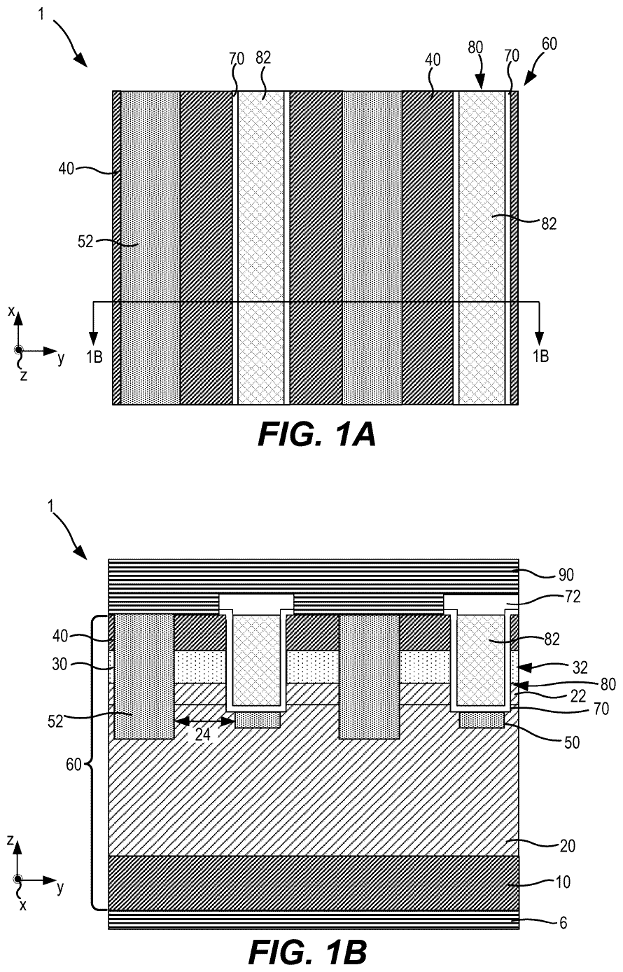

Two-part reference numerals that include two numbers separated by a dash (-) are sometimes used in the figures and the discussion that follows to identify instances of multiple like elements. The full reference number may be used to refer to individual instances of the like element while the first part of the reference number may be used to refer to the like elements collectively.

It will be appreciated that the sizes (e.g., the thicknesses) of various regions in the drawings are not drawn to scale to allow enlargement of other regions of the drawings. For example, the substrates and drift regions of the power semiconductor devices shown in the drawings are depicted as being much thinner in the figures than they are in practice so that details of thinner upper layers and regions of the semiconductor devices can be more clearly depicted.

### DETAILED DESCRIPTION

As discussed above, gate trench power MOSFETs often include trench shields underneath the gate trenches and/or support shields in between adjacent gate trenches of power MOSFETs that help protect the gate oxide layers that line the gate trenches from high electric fields during reverse blocking operation. The trench shields and support shields are formed by doping (typically by ion implantation) appropriate regions of the semiconductor layer structure with dopants having the same conductivity type as the dopants included in the channel regions of the device. While trench shields and support shields can significantly reduce the electric field levels in the gate oxide layers, thereby reducing the risk of dielectric breakdown, they also act to funnel the on-state currents through smaller regions (as the on-state currents flow around the p-type regions), thereby increasing the on-state resistance of the power MOSFET. Thus, there is an inherent trade-off between on-state resistance performance and device reliability in vertical gate trench power semiconductor devices.

Pursuant to embodiments of the present invention, gate trench power MOSFETs and other gate trench semiconductor devices are provided that may have improved trade-offs between on-state resistance performance and device reliability. The power semiconductor devices according to embodiments of the present invention have support shields which help protect the gate oxide layers lining the gate trenches from high electric field levels, particularly during reverse blocking operation. The support shields thus help protect the device from premature gate oxide breakdown, and thus improve the reliability of the semiconductor device. The support shields, however, funnel the on-state current through narrower JFET gaps, which acts to increase the on-state resistance of the device. The power semiconductor devices according to embodiments of the present invention include first and second sets of gate trenches that extend in different directions so that channel regions extend in multiple different directions within the semiconductor layer structure of the device. By providing channel regions that extend in multiple directions, the overall amount of channel area may be increased, which allows the on-state current to more easily spread throughout the semiconductor layer structure, helping to reduce the on-state resistance. Thus, the semiconductor devices according to embodiments of the present invention may exhibit both good reliability and good on-state resistance performance.

Gate trench power semiconductor devices that include trench shields underneath the gate trenches typically include so-called trench shield connection patterns that electrically connect the trench shields to the source metallization. The trench shield connection patterns may comprise implanted regions having the same conductivity type as the channel regions. Thus, for an n-type power semiconductor device the trench shield connection patterns comprise p-type regions in the semiconductor layer structure (and the discussion below will assume that the power semiconductor device is an n-type device). The trench shield connection patterns connect the trench shields directly to the source metallization or to the p-wells (which are connected to the source metallization through well contact regions). The trench shield connection patterns typically comprise stripes of p-type material that extend perpendicularly to the trench shields when the power semiconductor device is viewed from above. Since the trench shield connection patterns are p-type regions, they also may act as support shields as the electric fields will tend to terminate in the p-type trench shield connection patterns during reverse blocking operation, thereby helping to shield the gate oxide layers from the high electric field values. The trench shield connection patterns are typically spaced farther apart from each other than the trench shields (e.g., 2-200 microns apart) with the spacing between trench shield connection patterns selected to optimize on-state conduction and displacement current flow during the off-state. The trench shield connection patterns typically “intersect” the gate trenches when the semiconductor device is viewed from above as the trench shield connection patterns must necessarily connect to the trench shields that are underneath the respective gate trenches.

When a gate trench power semiconductor device only includes gate trenches that extend in one direction, the “primary” support shields (i.e., the support shields that do not act as trench shield connection patterns) extend in between the gate trenches, and hence the primary support shields never cross the gate trenches. However, once first and second sets of gate trenches are provided that extend in different directions, the gate trenches in at least one of the first and second sets of gate trenches will intersect the support shields. How the gate trenches and the support shields intersect may impact a number of performance parameters of the power semiconductor device, including the on-state resistance, the gate oxide lifetime (and hence device reliability), and the reliability of the electrical connections to the trench shields. Embodiments of the present invention disclose different ways that the gate trenches and the support shields may intersect to optimize these performance trade-offs for different applications.

In some embodiments, the power semiconductor devices may include first and second sets of gate trenches, where the gate trenches in the first and second sets extend in respective first and second perpendicular directions. In such embodiments, the primary support shields may extend in the first direction and the trench shield connection patterns (which act as secondary support shields) may extend in the second direction. In other embodiments, the gate trenches in the first set of gate trenches may extend in a first direction, and the gate trenches in the second set of gate trenches may have a zig-zag shape when viewed from above. Each zig-zag shaped gate trench may, for example, zig-zag along a longitudinal axis that extends in the second direction that is perpendicular to the first direction. For example, in silicon carbide, the equivalent faces in the crystallographic structure meet at angles of 60°. Thus, the first trenches may be formed along the (112̅0) face and the second trenches may have first sections that extend along the (1̅21̅0) face and second sections that extend along the (2̅110) face, all commonly known as equivalent a-face in 4H—SiC. Associating multiple equivalent faces in a zig-zag pattern allows maximization of the cell density in multiple directions to achieve lower conduction losses. Additionally, the zig-zag gate trench configuration also facilitates multiple equivalent off-axis faces which can exhibit higher carrier mobility. 4H-SiC epitaxy is often grown at a 4°-8° off-cut for growth convenience. This makes some offset of the equivalent face direction to the true on-axis counterpart, a crystallographic direction of the material if no off-cut is performed. The lower the off-set of the equivalent face in the material as compared to an on-axis cut, the higher the carrier mobility is reported in the literature. As an example, in an off-cut material, the (112̅0) face shows higher electron mobility than (1̅1̅20) face.

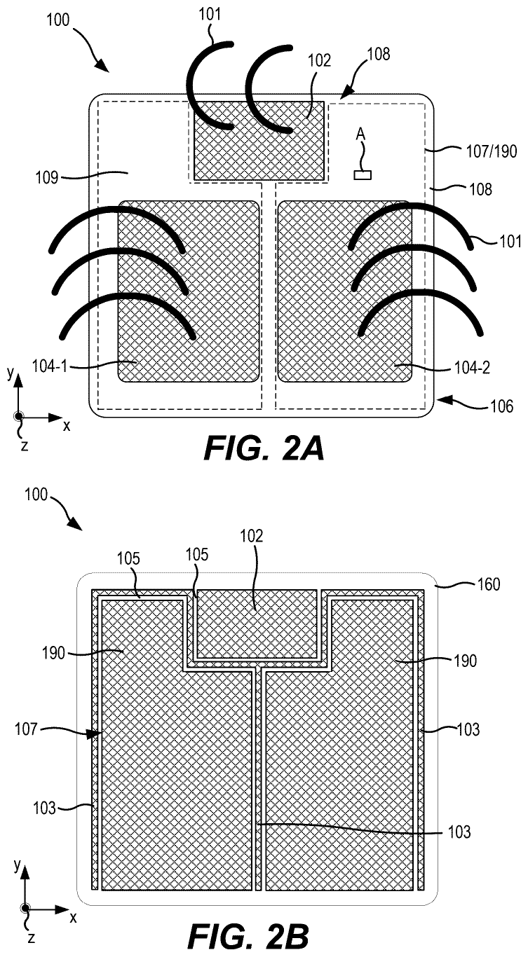

Embodiments of the present invention will now be described in more detail with reference to FIGS. 2A-12. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like. It will also be appreciated that the term MOSFET is used broadly to encompass devices that use both oxide-based gate dielectric layers and non-oxide gate dielectric layers (e.g., nitrides, high dielectric constant materials, etc.), and that the gate electrodes of the MOSFETs may comprise any conductive material (including semiconductor materials) and is not limited to metal gate electrodes.

FIG. 2A is a schematic top view of a gate trench silicon carbide power MOSFET 100 according to certain embodiments of the present invention. FIG. 2B is a schematic plan view of the power MOSFET 100 with an upper protective layer omitted to show the full gate and source metallization. In other words, FIGS. 2A and 2B show the outer appearance of power MOSFET 100 (FIG. 2A) and the design of the upper metallization layers (FIG. 2B). As the discussion below will make clear, the various embodiments of the present invention disclosed herein vary in terms of their gate trench and support shield designs, neither of which are visible in FIGS. 2A-2B. As such, all of the power MOSFETs discussed herein may have the design shown in FIGS. 2A-2B. It will also be appreciated that the various embodiments of the present invention discussed herein may have different configurations than the one specific configuration shown in FIGS. 2A-2B (e.g., different gate pad locations, different gate runner designs, different numbers of source pads, etc.).

Referring to FIG. 2A, power MOSFET 100 includes a gate pad 102 and one or more source pads 104-1, 104-2 that are each formed on the upper side of the semiconductor layer structure 160 (FIG. 2B). A metal drain pad 106 (not visible in FIGS. 2A-2B, but located on the bottom side of the power MOSFET 100 as shown by the arrow 106) is provided on the bottom side of the semiconductor layer structure 160. The gate pad 102, the source pads 104 and the drain pad 106 form the respective gate, source and drain terminals of power MOSFET 100. The gate and source pads 102, 104 may each be formed of a metal, such as aluminum, that bond wires can be readily attached to via conventional techniques such as thermo-compression or soldering. The drain pad 106 may likewise be a metal pad. A protective layer 109 such as a polyimide layer may cover the entire upper surface of power MOSFET 100 except for the gate and source pads 102, 104.

Still referring to FIG. 2A, the power MOSFET 100 includes a source metallization 190 (indicated by the dashed boxes in FIG. 2A) that electrically connects certain regions of the semiconductor layer structure 160 to the source pads 104-1, 104-2. The source metallization 190 may include, for example, an ohmic contact layer (e.g., a metal silicide layer) that directly contacts the semiconductor layer structure 160, one or more optional adhesion and or barrier metal layers, and a bulk metal layer. Typically, the source pads 104 are a part of the bulk metal layer that is exposed through the protective layer 109. Herein, the source metallization 190 will be illustrated as a single layer for simplicity, but it will be appreciated that it typically includes multiple layers and may have any appropriate form. The source metallization 190 may generally overlie or correspond to an “active region” 107 of the power MOSFET 100 where the unit cell transistors are located. An inactive region 108 of power MOSFET 100 surrounds the active region 107. The inactive region 108 may include a termination region that extends around the periphery of the MOSFET 100 that includes guard rings, junction termination elements or other termination structures (not shown), a gate pad region that underlies the gate pad 102, and gate bus regions.

Bond wires 101 are shown in FIG. 2A that may be used to connect the gate pad 102 and the source pads 104 to external circuits or the like. The drain pad 106 on the bottom side of power MOSFET 100 may be connected to an external circuit through, for example, an underlying submount (not shown).

FIG. 2B is another plan view of power MOSFET 100 with the polymide layer 109 omitted to expose the full source and gate metallization. As shown in FIG. 2B, the source metallization 190 extends throughout the active region 107 of the device. The gate metallization includes the gate pad 102 and a gate bus 103. The source metallization 190 is spaced apart from both the gate pad 102 and the gate bus 103 by an intermetal dielectric layer 105 so that a single metal layer may be used to form the source metallization and the gate metallization. The gate pad 102 is spaced apart from the gate bus 103 so that the gate current may pass through one or more lumped gate resistors (not visible in the figures) that are formed underneath the intermetal dielectric layer 105. The lumped gate resistors may, for example, improve the electromagnetic interference (“EMI”) performance of the device and/or improve the stability of long feedback loops that are created as the lengths of the gate electrodes are increased in order to increase the power handling capability of the device. The metal gate buses 103 extend around much of the periphery of the active region 107. The gate buses 103 may provide a low resistance path for distributing gate signals that are applied to the gate pad 102 to the gate electrodes 182 (discussed below) that extend throughout the active region 107.

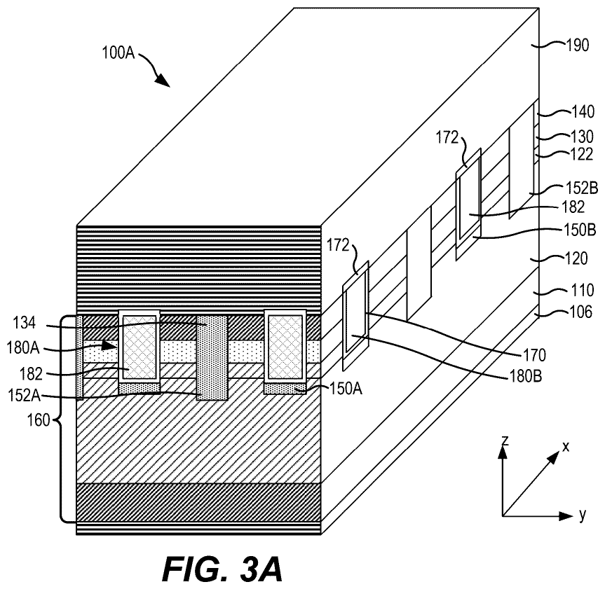

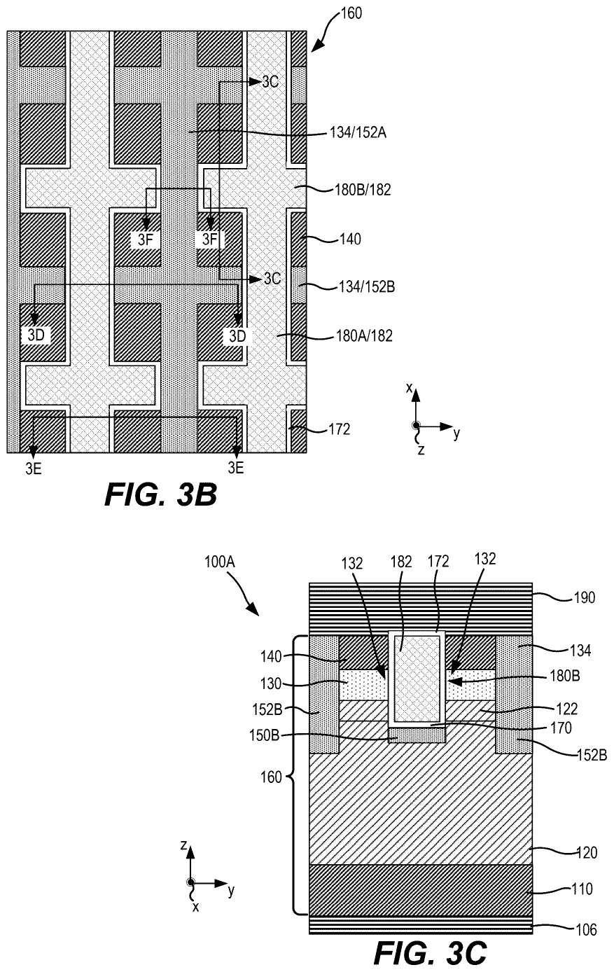

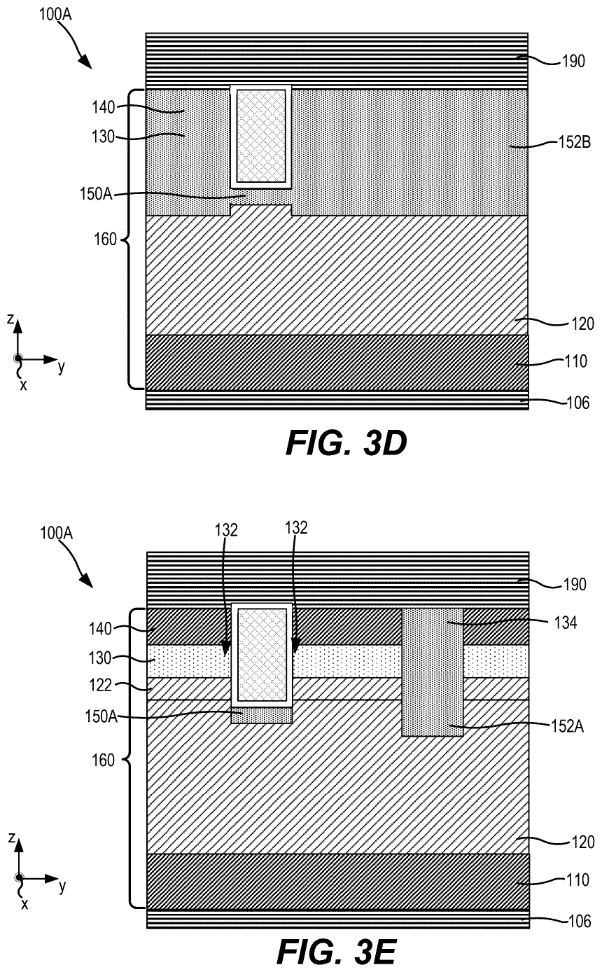

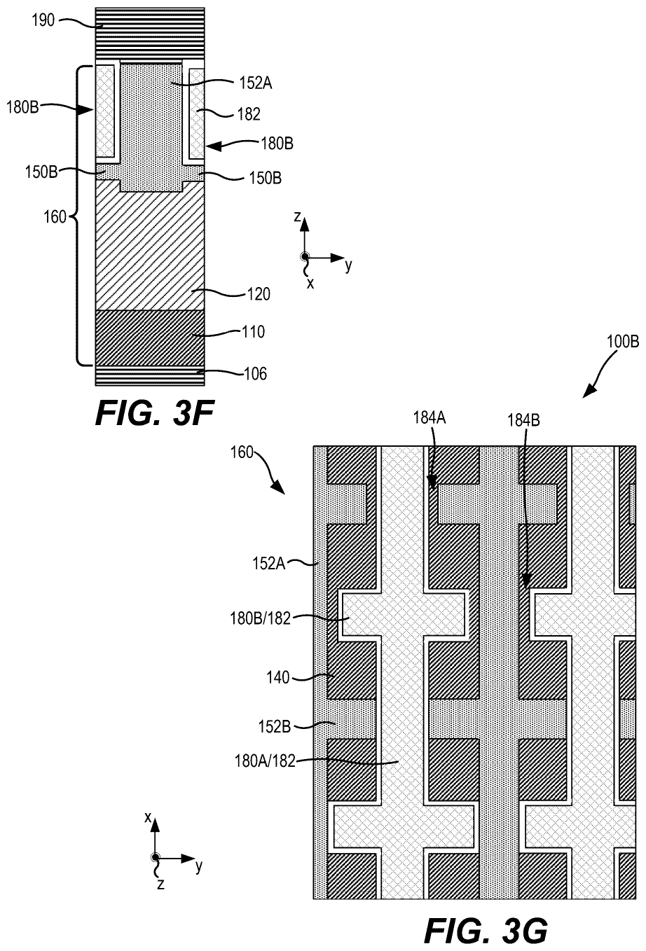

FIGS. 3A-3F illustrate a small portion of a power MOSFET 100A according to embodiments of the present invention. Power MOSFET 100A is of specific implementation of power MOSFET 100 and hence has the configuration shown in FIGS. 2A-2B. FIGS. 3A-3F illustrate the portion of power MOSFET 100A that corresponds to the region labeled A in FIG. 2A. More specifically, FIG. 3A is a schematic perspective view of region A, and FIG. 3B is a schematic top view of region A with the upper dielectric layers and the source metallization omitted to show the gate electrodes and the upper surface of the semiconductor layer structure. FIGS. 3C-3F are cross-sectional views taken along lines 3C-3C, 3D-3D, 3E-3E, and 3F-3F, respectively, of FIG. 3B with the upper dielectric layers and the source metallization that are omitted in FIG. 3B added for context.

Referring to FIGS. 3A-3B, power MOSFET 100A includes an n-type silicon carbide semiconductor substrate 110. The substrate 110 may comprise, for example, a single crystal 4H silicon carbide semiconductor substrate that is heavily-doped with n-type impurities (i.e., an n+ silicon carbide substrate). The dopant impurities may comprise, for example, nitrogen or phosphorous or other suitable dopants. In example embodiments, the n-type substrate 110 may have a doping concentration of, for example, between 1×10¹⁸ atoms/cm³ and 1×10²¹ atoms/cm³, although other doping concentrations may be used. The substrate 110 may be any appropriate thickness (e.g., in a range of about 50 microns to about 500 microns, such as about 100 microns to about 360 microns, or about 200 microns to about 300 microns, but thinner or thicker substrates are possible). Other substrates may be used without deviating from the scope of the present disclosure. Moreover, the substrate 110 may be partially or fully removed in some embodiments.

A lightly-doped n-type (n−) silicon carbide drift layer 120 is provided on an upper surface of the substrate 110. The drift layer 120 may also be referred to herein as a drift region 120. Typically, the drift layer 120 is formed via an epitaxial growth process on the silicon carbide substrate 110 and is doped during growth. The epitaxial growth process may be, for example, a chemical vapor deposition process, but other growth/formation processes may be used. The n-type drift region 120 may have, for example, a doping concentration of 1×10¹⁴ to 1×10¹⁷ dopants/cm³, with the doping level typically selected based on a blocking voltage rating of the device. In example embodiments, the n-type doping concentration of the drift region 120 may be in a range of about 1×10¹⁵/cm³ to about 2×10¹⁶/cm³ or in a range of about 5×10¹⁵/cm³ to about 1×10¹⁶. The dopants may be, for example, nitrogen dopants or phosphorous dopants or any other suitable dopants. In some cases, the drift region 120 may have a uniform or nearly uniform dopant concentration across a thickness of the drift region 120. In other cases, the drift region 120 may have a graded doping profile with depth. The drift region 120 may have a thickness in a range of about 1 micron to about 100 microns. In example embodiments, the drift region 120 may have a thickness in a range of about 3 microns to about 100 microns, about 6 microns to about 100 microns, about 3 microns to about 50 microns, about 3 microns to about 20 microns, about 4 microns to about 15 microns, or about 4 microns to about 10 microns.

In some embodiments, a more heavily doped JFET region 122 is formed in the upper portion of the drift region 120. The JFET region 122 is considered to be part of the drift layer 120, and has a higher doping concentration than the remainder of the drift region 120. In example embodiments, the JFET region 122 may have a peak doping concentration that is between twice and ten times the peak doping concentration of the lower portion of the drift layer 120. The JFET region 122 may be a continuous region or a plurality of discontinuous regions, and may have a relatively constant doping concentration or a graded doping concentration. In example embodiments, the peak doping concentration of the JFET region 122 may be between 1×10¹⁶ dopants/cm³ and 5×10¹⁷ dopants/cm³. The JFET region 122 may have a thickness (i.e., extent in the depth direction) of, for example, between 0.3 and 1.0 microns.

A plurality of moderately-doped (p) p-type silicon carbide well regions 130 (which may also be referred to herein as a “p-wells 130”) are formed on the upper surface of the n-type drift region 120. The p-wells 130 may be formed, for example, by epitaxial growth followed by an ion implantation process that is used to implant p-type dopants (e.g., aluminum, boron, gallium, indium) into the epitaxially grown semiconductor material. The p-wells 130 may, for example, have a peak doping concentration in a range of about 1×10¹⁶/cm³ to about 1×10¹⁸/cm³. In example embodiments, the peak doping concentration may be in the range of about 5×10¹⁶/cm³ to about 2×10¹⁷/cm³ or in the range of about 5×10¹⁶/cm³ to about 1×10¹⁷/cm³. In some embodiments, the concentration of dopants in the p-type well regions 130 may be higher than the concentration of dopants in the drift region 120. The p-wells 130 may have a thickness (i.e., extent in the depth direction) of, for example, between 0.3 and 0.6 microns.

Heavily-doped n-type (n+) silicon carbide source regions 140 are formed on or in upper portions of the respective p-wells 130. Each source region 140 may extend, for example, to a maximum depth of between 0.2 microns and 1.0 microns from the upper surface of the semiconductor layer structure 160. The source regions 140 may, for example, have a peak doping concentration in a range of about 1×10¹⁸/cm³ to about 5×10²¹/cm³, such as about 1×10¹⁹/cm³ to about 1×10²¹/cm³, such as about 5×10¹⁹/cm³ to about 5×10²⁰/cm³. The heavily doped n-type source region 140 may be formed by epitaxial growth followed by ion implantation of n-type dopants (e.g., nitrogen, phosphorus). In some embodiments, however, the n-type source region 140 may be formed by epitaxial growth.

A plurality of heavily-doped p-type silicon carbide well contact regions 134 are also on upper portions of the respective p-wells 130. The well contact regions 134 may be more heavily doped with p-type dopants than the p-wells 130. The well contact regions 134 may be formed, for example, by ion implantation. In some embodiments, however, the well contact regions 134 may be formed by epitaxial growth. The well contact regions 134 may be heavily doped with a p-type doping material at concentrations in a range of about 1×10¹⁹/cm³ to 1×10²¹ cm³, such as about 5×10¹⁹/cm³ to 5×10²⁰ cm³, such as about 5×10¹⁹/cm³ to 1×10²⁰ cm³. Each well contact regions 134 may be laterally adjacent one or more source regions 140 and may above a respective one of a plurality of support shields (which are discussed below). The well contact regions 134 are shown as being the upper portion of the support shields in the discussion that follows, but it will be appreciated that the well contact regions 134 may alternatively be separate regions.

The substrate 110, the drift region 120 (including the JFET region 122), the p-wells 130, the well contact regions 134, and the source regions 140 are all silicon carbide regions and are all part of the semiconductor layer structure 160 of power MOSFET 100. The semiconductor layer structure 160 further includes additional silicon carbide regions, discussed below, p-type trench shields 150A, 150B, p-type support shields 152A, 152B. The drift layer 120 and the substrate 110 together act as a common drain region for the power MOSFET 100. The drain pad 106 is formed on the substrate 110 opposite the drift region 120.

A plurality of first gate trenches 180A are formed in the upper surface of the semiconductor layer structure 160. Two first gate trenches 180A are visible in FIG. 3A. A longitudinal axis of each first gate trench 180A extends in the x-direction. Each first gate trench 180A may, for example, extend to a maximum depth of between 0.5 microns and 1.5 microns from the upper surface of the semiconductor layer structure 160. The first gate trenches 180A may be formed via an etching process. The first gate trenches 180A extend through the source regions 140, the p-wells 130 and into the drift region 120, as shown in FIGS. 3C-3F.

A gate dielectric layer 170 is provided in each first gate trench 180A to cover the sidewalls and bottom surface of the first gate trenches 180A. The gate dielectric layers 170 may be, for example, oxide layers, and may include one or more layers. In some examples, each gate dielectric layer 170 includes one or more of SiO₂, SiN, Al₂O₃, MgOₓ, MgNₓ, ZnO, SiNₓ, SiOₓ, HfOₓ or other suitable dielectric layers. The gate oxide layers 170 may be formed generally conformally within the respective first gate trenches 180A. As will be discussed below, in some embodiments, the first gate trenches 180A may be interconnected by second gate trenches so that a monolithic gate dielectric layer 170 and gate electrode 182 may fill all of the gate trenches.

A gate electrode 182 is formed in each first gate trench 180A on the gate dielectric layer 170. The gate electrodes 182 may comprise a conductive material such as a silicide (e.g., NiSi, TiSi, WSi, CoSi), a metal (e.g., Ti, Ta or W), a metal nitride (e.g., TiN, TaN or WN) or a doped semiconductor material (e.g., doped polycrystalline silicon). Most silicon carbide based power MOSFETs have doped polysilicon gate electrodes 182. The gate oxide layers 170 may insulate the gate electrodes 182 from the semiconductor layer structure 160, thereby preventing the gate electrodes 182 from short circuiting to the semiconductor layer structure 160. Each gate electrode 182 may connect to one of the gate buses 103 (see FIG. 2B). In the depicted embodiment, the gate electrodes 182 are recessed so that the upper surface of each gate electrode 182 is even with or slightly below an upper surface of the semiconductor layer structure 160. It will be appreciated that in other embodiments the gate electrodes 182 may extend above and onto the upper surface of the semiconductor layer structure 160, with the gate oxide layer 170 also extending onto the upper surface of the semiconductor layer structure 160 to insulate the gate electrodes 182 from the upper surface of the semiconductor layer structure 160. The gate electrodes 182 may be electrically connected to the gate pad 102 through the gate buses 103.

A source metallization 190 is on the n-type source regions 140 and p-type well contact regions 134. The source metallization 190 may provide an ohmic contact with the semiconductor layer structure 160. The source metallization 190 may include, for example, one or more metals such as nickel, titanium, tungsten or aluminum, or alloys or layered stacks of these or other suitable materials. In some embodiments, the source metallization 190 may include a separate ohmic contact layer (not shown), for instance, made of nickel silicide that may be formed by depositing a nickel layer which may be annealed into the silicon carbide semiconductor layer structure 160 to form the nickel silicide ohmic contact. Additional metal layers may be provided including, for example, one or more adhesion layers and/or one or more diffusion barrier layers.

Intermetal dielectric layers 172 are formed that cover each gate electrode 182. The intermetal dielectric layers 172 insulate the source metallization 190 from the gate electrodes 182.

Moderately doped p-type first trench shields 150A are formed underneath each first gate trench 180A. Each first trench shields 150A may extend the full length of each first gate trench 180A. In example embodiments, the first trench shields 150A may have p-type doping concentrations range of about 1×10¹⁸/cm³ to about 1×10²¹/cm³, such as about 5×10¹⁸/cm³ to about 5×10²⁰/cm³, such as about 1×10¹⁹/cm³ to about 1×10²⁰/cm³. The first trench shields 150A may, for example, be formed by ion implantation (typically into the bottoms of the first gate trenches 180A). The first trench shields 150A may act to reduce electric field levels formed in the gate dielectric layer 170 during operation of power MOSFET 100A. In some embodiments, the first trench shields 150A may be omitted.

A plurality of first support shields 152A are formed in the semiconductor layer structure 160 in between adjacent ones of the first gate trenches 180A. The first support shields 152A may be formed, for instance, by implanting p-type dopants into selected regions of the semiconductor layer structure 160. Each first support shield 152A may be moderately or heavily doped with a p-type doping material (p+) at concentrations in a range of about 5×10¹⁶/cm³ to about 1×10²¹/cm³, such as about 1×10¹⁷/cm³ to about 5×10²⁰/cm³, such as about 5×10¹⁷/cm³ to about 1×10²⁰/cm³. In some embodiments, the concentration of dopants in the first support shields 152A may be at least 5 times higher than a concentration of dopants in the drift layer 120, or at least about 10 times higher. The first support shields 152A may block electric fields during reverse blocking operation of power MOSFET 100A. In some embodiments, the first trench shields 150A may extend to a same depth as the first support shields 152A in the semiconductor layer structure 160. In other embodiments, the first trench shields 150A may extend to a different depth (e.g., deeper or not as deep). In the illustrated embodiment, the support shields 152A extend deeper into the semiconductor layer structure 160 than the first trench shields 150A.

A plurality of second gate trenches 180B are formed in the upper surface of the semiconductor layer structure 160. Two second gate trenches 180B are visible in FIG. 3A. A longitudinal axis of each second gate trench 180B extends in the y-direction. Thus, longitudinal axes of the second gate trenches 180B extend perpendicularly to the longitudinal axes of the first gate trenches 180A. Each second gate trench 180B may, for example, extend to a maximum depth of between 0.5 microns and 1.5 microns from the upper surface of the semiconductor layer structure 160, and may have the same depth as the first gate trenches 180B. The second gate trenches 180B may be formed in the same etching process used to form the first gate trenches 180A. The second gate trenches 180B extend through the source regions 140, the p-wells 130 and into the drift region 120.

A gate dielectric layer 170 and a gate electrode 182 are provided in each second gate trench 180B, and intermetal dielectric layers 172 are formed that cover the gate electrode 182 in each second gate trench 180B. The gate dielectric layers 170, gate electrodes 182 in the second gate trenches 180B and the intermetal dielectric layers 172 covering the same may be identical to the gate dielectric layers 170, gate electrodes 182 in the first gate trenches 180A and the intermetal dielectric layers 172 covering the same (except that they extend in a different direction) and hence further description thereof will be omitted. The source metallization 190 covers the first and second gate trenches 180A, 180B and is insulated from the gate electrodes by the intermetal dielectric layers 172.

Moderately doped p-type second trench shields 150B may also be formed underneath each second gate trench 180B. Each second trench shields 150B may extend the full length of a respective one of the second gate trenches 180B. The second trench shields 150B may, for example, be formed by ion implantation (typically into the bottoms of the second gate trenches 180B). The second trench shields 150B may act to reduce electric field levels formed in the gate dielectric layer 170 during operation of power MOSFET 100A. In some embodiments, the second trench shields 150B may be omitted

A plurality of second support shields 152B are formed in the semiconductor layer structure 160 in between adjacent ones of the second gate trenches 180B. The second support shields 152B may be formed, for instance, by implanting p-type dopants into selected regions of the semiconductor layer structure 160. Each second support shield 152B may be moderately or heavily doped with a p-type doping material (p+) at concentrations in a range of about 5×10¹⁶/cm³ to about 1×10²¹/cm³, such as about 1×10¹⁷/cm³ to about 5×10²⁰/cm³, such as about 5×10¹⁷/cm³ to about 1×10²⁰/cm³. In some embodiments, the concentration of dopants in the second support shields 152B may be at least 5 times higher than a concentration of dopants in the drift layer 120, or at least about 10 times higher. The second support shields 152B may block electric fields during reverse blocking operation of power MOSFET 100A. In the depicted embodiment, the first and second support shields 152A, 152B each extend deeper into the semiconductor layer structure 160 than do the trench shields 150B.

The second support shields 152B may act as trench shield connection patterns that electrically connect to the first trench shields 150A (which extend underneath the first gate trenches 180A), electrically connecting the first trench shields 150A to the source metallization 190. Likewise, the first support shields 152A may act as trench shield connection patterns that electrically connect to the second trench shields 150B (which extend underneath the second gate trenches 180B), electrically connecting the second trench shields 150B to the source metallization 190. FIG. 3D illustrates how a second support shield 152B electrically connects a first trench shield 150A to the source metallization 190, and FIG. 3F shows how a first support shield 152A electrically connects two second trench shields 150B to the source metallization 190.

As best shown in FIGS. 3C and 3E, the portions of each p-well 130 that are adjacent a first gate trench 180A or adjacent a second gate trench 180B act as channel regions 132 during on-state operation. In particular, when appropriate bias voltages are applied to the gate, drain and source terminals 102, 104, 106 of power MOSFET 100, a conductive n-type inversion layer is formed in the portion of each p-well 130 that is adjacent a gate electrode 182 (i.e., in the channel regions 132), allowing current to flow through the channel regions 132. Thus, a current path is created between the source and drain terminals 104, 106 that flows through the source metallization 190, the source regions 140, the channel regions 132, the drift region 120, the substrate 110 and the drain contact 106. The power MOSFET 100 may be turned off by changing the applied bias voltages (typically by lowering or removing the gate bias voltage).

Referring again to FIG. 3B, it can be seen that the first gate trenches 180A and the second gate trenches 180B form a two-dimensional grid of gate trenches when power MOSFET 100A is viewed from above. The first gate trenches 180A extend continuously in the semiconductor layer structure 160 with their longitudinal axes extending in the x-direction. The second gate trenches 180B have longitudinal axes that extend in the y-direction. The second gate trenches 180B, however, are discontinuous gate trenches that comprise a plurality of spaced-apart gate trench segments. The first support shields 152A extend continuously in the semiconductor layer structure 160 with their longitudinal axes extending in the x-direction. The second support shields 152B have longitudinal axes that extend in the y-direction. The second support shields 152B are discontinuous support shields that comprise a plurality of spaced-apart support shield segments.

As is readily apparent from FIG. 3B, the second gate trenches 180B are formed to be discontinuous in order to allow the first support shields 152A to extend continuously in the semiconductor layer structure 160 without physically intersecting the second gate trenches 180B. Similarly, the second support shields 152B are formed to be discontinuous in order to allow the first gate trenches 180A to extend continuously in the semiconductor layer structure 160 without physically intersecting the second support shields 152B.

The provision of the second support shields 152B and the second trench shields 150B increases the amount of p-type shielding material that is present in the semiconductor layer structure 160. As such, the gate dielectric layers 170 of power MOSFET 100A may have enhanced protection during reverse blocking operation from high electric fields, and hence power MOSFET 100A may exhibit improved reliability (i.e., will have a reduced failure rate). The provision of the first support shields 152A, however, increases the pitch of power MOSFET 100A, which reduces the number of first gate trenches 180A per unit distance, and the provision of the second support shields 152B eliminates some of the channel area along the first gate trenches 180A. These reductions in channel area act to increase the on-state resistance of power MOSFET 100A as compared to a conventional device. However, due to the provision of the second gate trenches 180B, additional channel area is provided on either side of each second gate trench segment 180B so that channel regions 132 are provided that extend in both the x-direction and the y-direction. This increase in the total amount of channel area helps reduce the on-state resistance. Thus, power MOSFET 100A may provide an improved tradeoff between reliability and on-state resistance performance.

Referring to FIGS. 3A-3F, pursuant to some embodiments of the present invention, semiconductor devices such as power MOSFET 100A are provided that comprise a semiconductor layer structure 160 that comprises a drift region 120 having a first conductivity type, a plurality of continuous first gate trenches 180A in an upper surface of the semiconductor layer structure 160, and a plurality of second gate trenches 180B in the semiconductor layer structure 160, the second gate trenches 180B intersecting the first gate trenches 180A. The power MOSFET 100A may further comprise a gate dielectric layer 170 and a gate electrode 182 in each of the first gate trenches 180A and in each of the second gate trenches 180B. The first gate trenches 180A extend in parallel to each other and each first gate trench 180A has a longitudinal axis that extends in a first direction (the x-direction).

As can also be seen from FIGS. 3A-3F, pursuant to other embodiments of the present invention, semiconductor devices such as power MOSFET 100A are provided that comprise a semiconductor layer structure 160 that comprises a drift region 120 having a first conductivity type. A plurality of parallel first gate trenches 180A are formed in the semiconductor layer structure 160, where each first gate trench 180A has a respective first longitudinal axis that extends in a first direction (the x-direction), and a plurality of parallel second gate trenches 180B are formed in the semiconductor layer structure 160, where each second gate trench 180B has a respective second longitudinal axes that extends in a second direction (the y-direction) that intersects the first direction (the x-direction). The power MOSFET 100A further comprises a plurality of parallel first support shields 152A that have the second conductivity type in the semiconductor layer structure 160, where the first support shields 152A have respective third longitudinal axes that extend in the first direction (the x-direction). Power MOSFET 100A further comprises a plurality of parallel second support shields 152B that have the second conductivity type in the semiconductor layer structure 160, where the second support shields 152B have respective fourth longitudinal axes that extend in the second direction (the y-direction). The first gate trenches 180A are continuous gate trenches and the second gate trenches 180B are discontinuous gate trenches. The first support shields 152A are continuous support shields and the second support shields 152B are discontinuous support shields.

Still referring to FIGS. 3A-3F, pursuant to still further embodiments of the present invention, semiconductor devices such as power MOSFET 100A are provided that comprise a semiconductor layer structure 160 that comprises a drift region 120 having a first conductivity type, a plurality of parallel continuous first gate trenches 180A in the semiconductor layer structure 160 that have respective first longitudinal axes that extend in a first direction (the x-direction), a plurality of parallel discontinuous second gate trenches 180B in the semiconductor layer structure 160 that have respective second longitudinal axes that extend in a second direction (the y-direction) that intersects the first direction (the x-direction), where each discontinuous second gate trench 180B comprises a plurality of colinear spaced apart segments. Power MOSFET 100A further comprises a plurality of parallel first support shields 152A that have the second conductivity type in the semiconductor layer structure 160. The first support shields 152A have respective third longitudinal axes that extend in the first direction (the x-direction). The first support shields 152A are continuous support shields, and power MOSFET 100A further comprises a plurality of parallel second support shields 152B that have the second conductivity type in the semiconductor layer structure 160 and that have respective fourth longitudinal axes that extend in the second direction (the y-direction). The second support shields 152B are discontinuous support shields. Ends of at least some of the segments of the second gate trenches 180B abut the continuous first support shields 152A.

Still referring to FIGS. 3A-3F, pursuant to yet additional embodiments of the present invention, semiconductor devices such as power MOSFET 100A are provided that comprise a semiconductor layer structure 160 comprising a drift region 120 having a first conductivity type, a plurality of parallel first gate trenches 180A in the semiconductor layer structure 160 that have respective first longitudinal axes that extend in a first direction, a plurality of parallel second gate trenches 180B in the semiconductor layer structure 160 that have respective second longitudinal axes that extend in a second direction that is perpendicular to the first direction so that the first gate trenches 180A and the second gate trenches 180B form a gate trench mesh that defines a plurality of mesas in the semiconductor layer structure 160. Power MOSFET 100A further comprises a plurality of first support shields 152A in the semiconductor layer structure 160 that have the second conductivity type.

It will be appreciated that the first and second gate trenches 180A, 180B may have the same widths or different widths and/or the same depths or different depths. The spacing between adjacent first gate trenches 180A may be the same as or different than the spacing between adjacent second gate trenches 180B. The same is true in the other embodiments of the present invention discussed below.

FIG. 3G is a schematic top view of a power MOSFET 100B that is a modified version of the power MOSFET 100A of FIG. 3A with the upper dielectric layers and the source metallization 190 omitted to show the gate electrodes and the upper surface of the semiconductor layer structure.

Power MOSFET 100B may be identical to power MOSFET 100A, except that in power MOSFET 100B first gaps 184A are provided between some of the first gate trenches 180A and corresponding ones of the second support shields 152B, and second gaps 184B are provided between some of the second gate trenches 180B and corresponding ones of the first support shields 152A. These gaps 184A, 184B create additional channel regions 132 within the active region of power MOSFET 100B so that power MOSFET 100B has more channel area than power MOSFET 100A. The gaps 184B are formed by shortening the segments of the second gate trenches 180B (and the second trench shields 150B thereunder), and the gaps 184A are formed by shortening the segments of the second support shields 152B. Shortening the segments of the second trench shields 150B and the second support shields 152B may reduce to an extent the ability of power MOSFET 100B to shield the gate dielectric layers 170 from high electric field values during reverse blocking operation as compared to power MOSFET 100A, but the overall reduction may be minimal. Thus, FIG. 3G illustrates a design modification that may further facilitate reducing the on-state resistance with only a small impact on the reliability of the power MOSFET. As shown in FIG. 3G, the first gaps 184A are only provided along some of the second support shields 152B and the second gaps 184B are only provided along some of the second gate trenches 180B. This ensures that the first and second trench shields 150A, 150B have electrical connections to the source metallization 190.

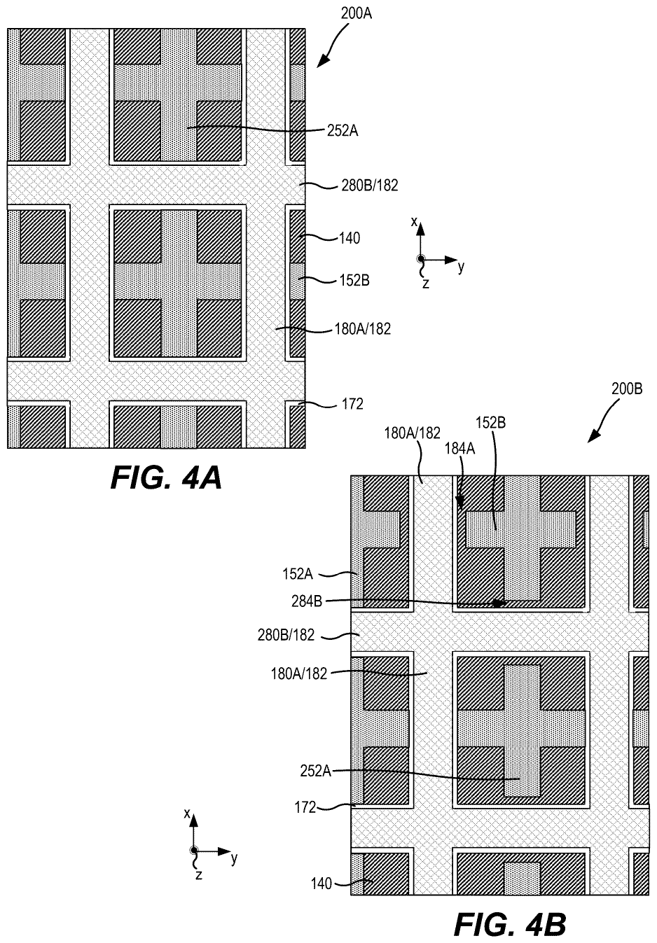

FIG. 4A is a schematic top view of a power MOSFET 200A according to further embodiments of the present invention. Power MOSFET 200A may appear the same as power MOSFET 100, and hence FIGS. 2A and 2B accurately depict power MOSFET 200A, and FIG. 4A shows the portion of power MOSFET 200A that corresponds to the box labelled A in FIG. 2A. The upper dielectric layers and the source metallization are omitted in FIG. 4A to show the gate electrodes and the upper surface of the semiconductor layer structure of power MOSFET 200A.

As can be seen by comparing FIGS. 3B and 4A, power MOSFET 200A differs from power MOSFET 100A in that power MOSFET 200A replaces the discontinuous second gate trenches 180B included in power MOSFET 100A with continuous second gate trenches 280B, and replaces the continuous first support shields 152A included in power MOSFET 100A with discontinuous first support shields 252A. As a result, power MOSFET 200A may have a continuous gate mesh design where the first and second gate trenches 180A, 180B are fully interconnected so that a single monolithic gate oxide layer 170 and a single monolithic gate electrode 182 are formed within the continuous gate trench structure. Otherwise, the design of power MOSFET 200A may be identical to the design of power MOSFET 100A. As can be seen by comparing FIGS. 3B and 4A, power MOSFETS 100A and 200A may have the same amount of channel area, while power MOSFET 100A may have extra support shield area as compared to power MOSFET 200A. Thus, power MOSFET 100A may provide overall better performance than power MOSFET 200A.

FIG. 4B is a schematic top view of a power MOSFET 200B according to further embodiments of the present invention that is a modified version of power MOSFET 200A of FIG. 4A. Power MOSFET 200B may appear the same as power MOSFET 100, and hence FIGS. 2A and 2B accurately depict power MOSFET 200B, and FIG. 4B depicts the portion of power MOSFET 200B that corresponds to the box labelled A in FIG. 2A. The upper dielectric layers and the source metallization are omitted in FIG. 4B to show the gate electrodes and the upper surface of the semiconductor layer structure of power MOSFET 200B.

As can be seen by comparing FIGS. 4A and 4B, power MOSFET 200B differs from power MOSFET 200A in that power MOSFET 200B includes a plurality of the first gaps 184A that are discussed above with reference to FIG. 3G. As shown, the first gaps 184A are provided between selected ones of the first gate trenches 180A and corresponding ones of the second support shields 152B. In addition, power MOSFET 200B further includes second gaps 284B that are provided between selected ones of the second gate trenches 280B and corresponding ones of the first support shields 152A. These gaps 184A, 284B create additional channel area within the active region of power MOSFET 200B so that power MOSFET 200B has more channel area than power MOSFET 200A. The gaps 184A, 284B are formed by shortening the segments of the first support shields 252A and the second support shields 152B as compared to the corresponding segments in power MOSFET 200A. Shortening the first and second support shield segments 252A, 152B may reduce to an extent the ability of power MOSFET 200B to shield the gate dielectric layers 170 from high electric field values during reverse blocking operation as compared to power MOSFET 200A, but the overall reduction may be minimal. Thus, FIG. 4B illustrates a design modification that may further facilitate reducing the on-state resistance with only a small impact on the reliability of the power MOSFET. As shown in FIG. 4B, the first gaps 184A are only provided along some of the second support shields 152B and the second gaps 284B are only provided along some of the first support shields 252A. This ensures that the first and second trench shields 150A, 150B have electrical connections to the source metallization 190.

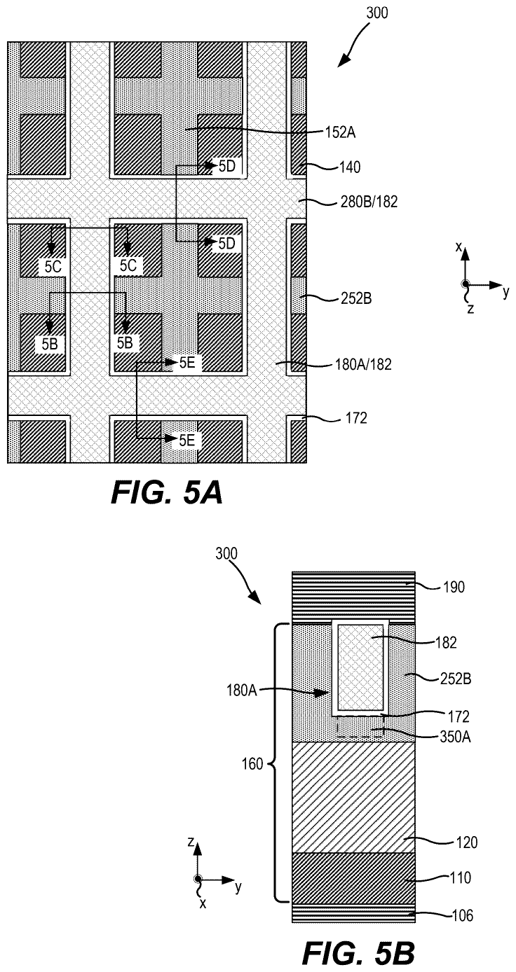

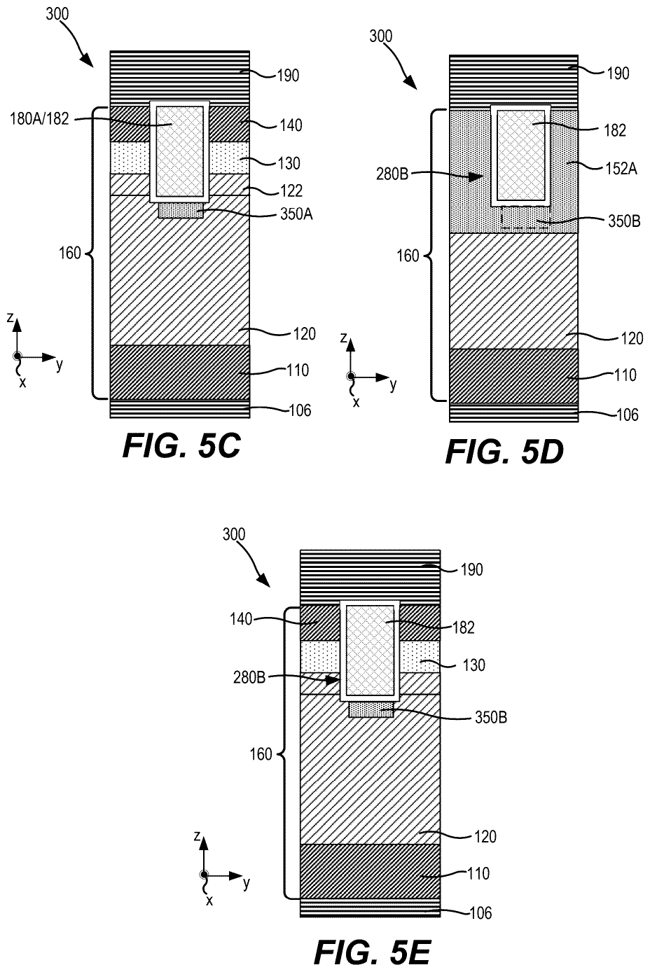

FIGS. 5A-5E illustrate a power MOSFET 300 according to further embodiments of the present invention. FIGS. 2A and 2B also accurately depict power MOSFET 300. FIG. 5A is a schematic top view of the portion of power MOSFET 300 that corresponds to the box labelled A in FIG. 2A, with the upper dielectric layers and the source metallization omitted to show the gate electrodes and the upper surface of the semiconductor layer structure of power MOSFET 200A. FIGS. 5B-5E are cross-sectional views taken along lines 5B-5B, 5C-5C, 5D-5D, and 5E-5E, respectively, of FIG. 5A with the upper dielectric layers and the source metallization that are omitted in FIG. 5A added for context.

Power MOSFET 300 of FIGS. 5A-5E is similar to power MOSFET 200A of FIG. 4A, except that in power MOSFET 300, continuous first and second support shields 152A, 252B replace the discontinuous first and second support shields 252A, 152B included in power MOSFET 200A. Otherwise, the design of power MOSFET 300 may be identical to the design of power MOSFET 200A.

Referring again to FIGS. 3D and 3F, it can be seen that the second support shields 152B electrically connect to the first trench shields 150A that are underneath the first gate trenches 180A and that the first support shields 152A electrically connect to the second trench shields 150B that are underneath the second gate trenches 180B. These electrical connections are used to connect the first and second trench shields 150A, 150B to the source metallization 190. For these electrical connections to be formed, it is necessary that the first and second trench shields 150A, 150B extend to the edges of the respective first and second gate trenches 180A, 180B, as shown in FIG. 3E.

In practice, the trench shields in a power MOSFET may be narrower than their associated gate trenches because the trench shields are formed by implanting ions into the bottom of the associated gate trenches. During this ion implantation process, some p-type dopant ions (for an n-type device) will implant into the sidewalls of each gate trench, both because the gate trenches may not have perfectly vertical sidewalls and because some dopant ions will scatter off of the bottoms of the gate trenches and implant into the sidewalls thereof. These dopant ions may degrade the n-type conductivity of the portions of the drift region that form the lower portions of the sidewalls of the gate trenches, which may increase the on-state resistance. In fact, if enough p-type ions are implanted into the lower sidewalls of the gate trenches, the MOSFET may no longer operate properly. To avoid these potential problems, the sidewalls of the gate trenches are often oxidized after the trench shields are formed, and the oxidized material is then removed via an etching step. This process acts to increase the width of each gate trench and, as a result, the gate trenches may be wider than their associated trench shields. If the above-described process is used, small gaps may exist between each trench shield and the trench shield connection patterns, and hence the trench shields and the trench shield connection patterns may not be electrically connected to each other. This may significantly degrade the effectiveness of the trench shields in terms of their ability to block high electric fields during reverse blocking operation. In order to avoid this potential problem, a pair of angled ion implantation processes may be used to form the trench shields to ensure that the trench shields are at least as wide as the gate trenches in the finished device. However, the use of angled ion implantation processes increases the manufacturing costs.

As shown in FIGS. 5C and 5E, power MOSFET 300 may include first and second trench shields 350A, 350B that are narrower than the corresponding first and second gate trenches 180A, 180B. Thus, the first and second trench shields 350A, 350B may readily be formed using non-angled ion implantation processes. The first and second support shields 152A, 252B are continuous structures that extend as uninterrupted stripes through the semiconductor layer structure 160. In the depicted embodiment the first and second support shields 152A, 252B extend deeper into the semiconductor layer structure 160 than do the first and second trench shields 350A, 350B. The first and second support shields 152A, 252B may be formed by ion implantation before the first and second gate trenches 280A, 180B are formed. The first and second trench shields 350A, 350B may be formed by ion implantation after the first and second gate trenches 180A, 180B are formed. Note that in regions where the first and second support shields 152A, 252B intersect the first and second trench shields 350A, 350B the p-type doping concentration may be higher than in other regions as these regions of the device will receive two p-type implants.

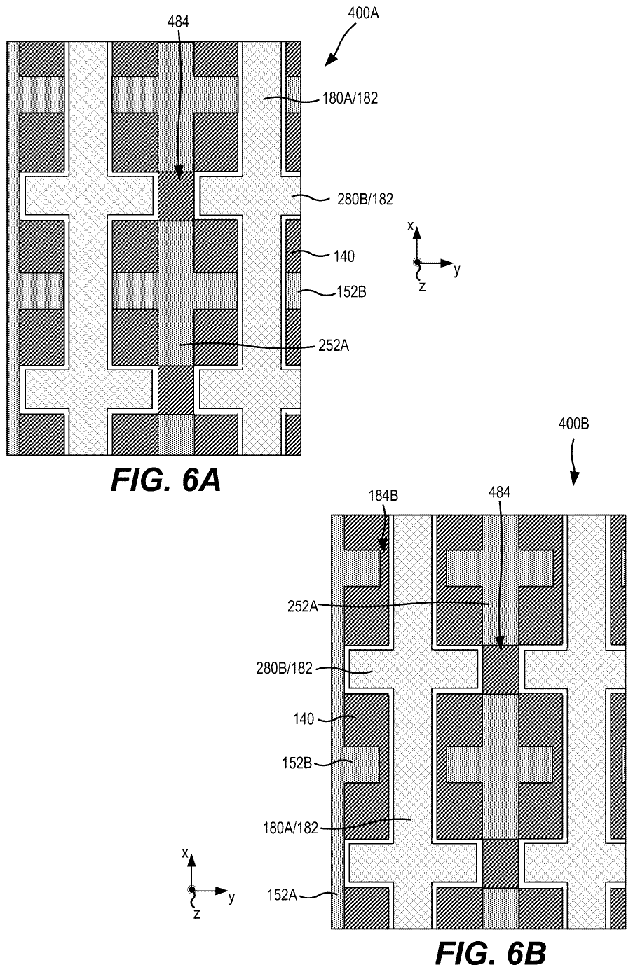

FIG. 6A is a schematic top view of a power MOSFET 400A according to yet additional embodiments of the present invention that corresponds to the box labelled A in FIG. 2A. The upper dielectric layers and the source metallization are omitted in FIG. 6A to show the gate electrodes and the upper surface of the semiconductor layer structure.

As can be seen by comparing FIGS. 3B and 6A, power MOSFET 400A differs from power MOSFET 100A in that power MOSFET 400A replaces some of the continuous first support shields 152A included in power MOSFET 100A with discontinuous first support shields 252A. As a result, power MOSFET 400A has increased channel area as compared to power MOSFET 100A due to the gaps 484 in the first support shields 252A. Power MOSFET 400A also includes some continuous first support shields 152A that provide electrical connections between the source metallization 190 and the second trench shields 150B.

FIG. 6B is a schematic top view of a power MOSFET 400B that is a modified version of the power MOSFET 400A of FIG. 6A. Power MOSFET 400B is nearly identical to power MOSFET 400A of FIG. 6A, with the one difference being that power MOSFET 400B further includes gaps 184B between selected ones of the second support shields 152B and the first gate trenches 180A. As discussed above, the gaps 184B increase the amount of channel area, which lowers the on-state resistance.

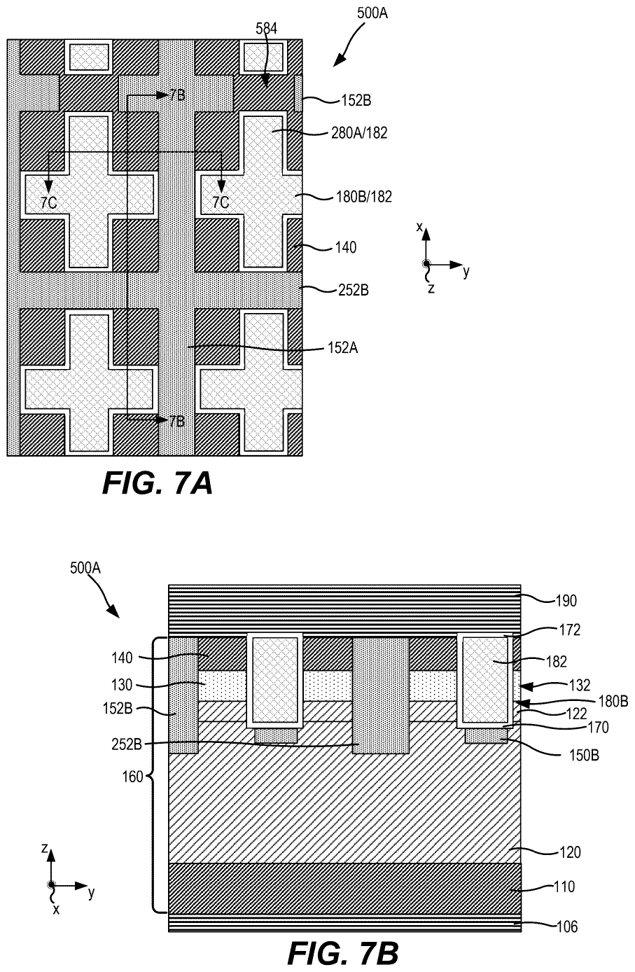

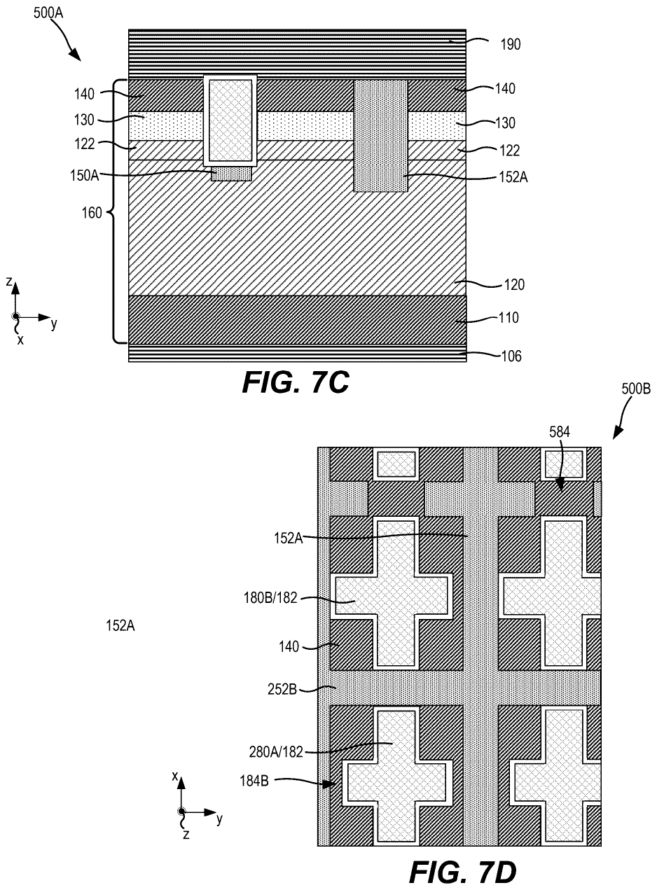

FIG. 7A is a schematic top view of yet another power MOSFET 500A according to embodiments of the present invention with the upper dielectric layers and the source metallization omitted to show the gate electrodes and the upper surface of the semiconductor layer structure. Once again, the view of FIG. 7A corresponds to the box labelled A in FIG. 2A. FIGS. 7B and 7C are cross-sectional views taken along lines 7B-7B and 7C-7C of FIG. 7A, respectively, with the upper dielectric layers and the source metallization that are omitted in FIG. 7A added for context.

As can be seen by comparing FIGS. 3B and 7A, power MOSFET 500A differs from power MOSFET 100A in that power MOSFET 500A replaces the continuous first gate trenches 180A included in power MOSFET 100A with discontinuous first gate trenches 280A. Otherwise, power MOSFET 500A is identical to power MOSFET 100A. While not explicitly shown in the figures, the first support shields 152A provide an electrical connection between the source metallization 190 and the second trench shields 150B. As shown in FIG. 7A, some continuous second support shields 252B are provided that electrically connect the first trench shields 150A to the source metallization 190. Power MOSFET 500A may have increased channel area as compared to power MOSFET 100A.

FIG. 7D is a schematic top view of a power MOSFET 500B that is a modified version of the power MOSFET 500A of FIG. 7A. Power MOSFET 500B is nearly identical to power MOSFET 500A of FIG. 7A, with the one difference being that power MOSFET 500B includes the gaps 184B between selected ones of the first support shields 152A and the second gate trenches 180B. As discussed above, the gaps 184B increase the amount of channel area, which lowers the on-state resistance.

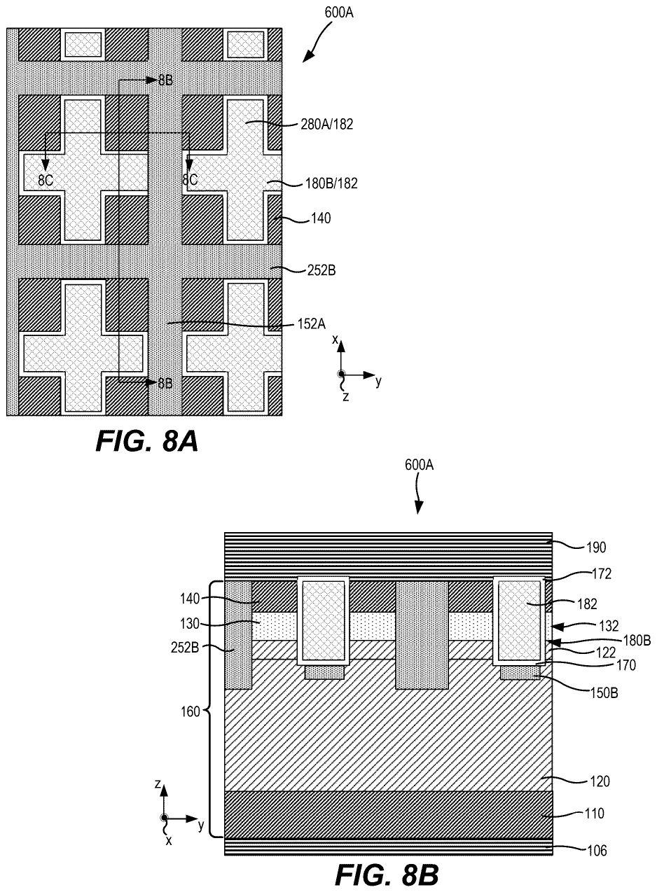

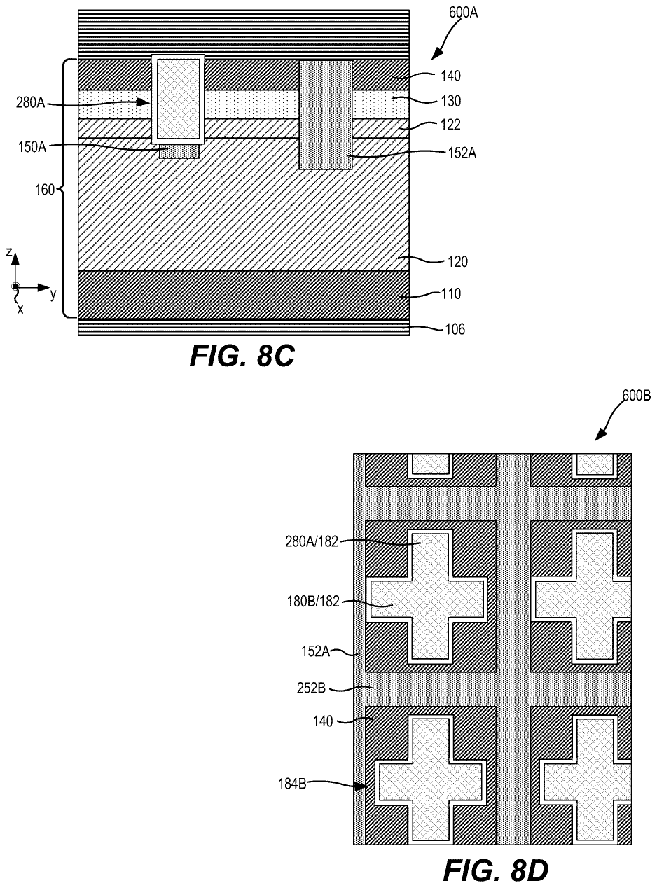

FIG. 8A is a schematic top view of still another power MOSFET 600A according to embodiments of the present invention with the upper dielectric layers and the source metallization omitted to show the gate electrodes and the upper surface of the semiconductor layer structure. The view of FIG. 8A corresponds to the box labelled A in FIG. 2A. FIGS. 8B and 8C are cross-sectional views taken along lines 8B-8B and 8C-8C of FIG. 8A, respectively, with the upper dielectric layers and the source metallization that are omitted in FIG. 8A added for context.

Power MOSFET 600A differs from the previously-described embodiments in that power MOSFET 600A includes continuous first and second support shields 152A, 252B and discontinuous first and second gate trenches 280A, 180B. In power MOSFET 600A, the continuous first and second support shields 152A, 252B define a grid when the power MOSFET is viewed from above, and a plurality of cross-shaped gate electrodes 182 are formed within the rectangular regions defined by the grid. The continuous first and second support shields 152A, 252B may provide a high degree of protection to the gate dielectric layers 170. This increased protection comes at the expense of less channel area as compared to various of the other power MOSFETs disclosed herein.

FIG. 8D is a schematic top view of a power MOSFET 600B that is a modified version of the power MOSFET 600A of FIG. 8A. Power MOSFET 600B is nearly identical to power MOSFET 600A of FIG. 8A, with the one difference being that power MOSFET 600B includes the gaps 184B between selected ones of the first support shields 152A and the second first gate trenches 180B. As discussed above, the gaps 184B increase the amount of channel area, which lowers the on-state resistance.

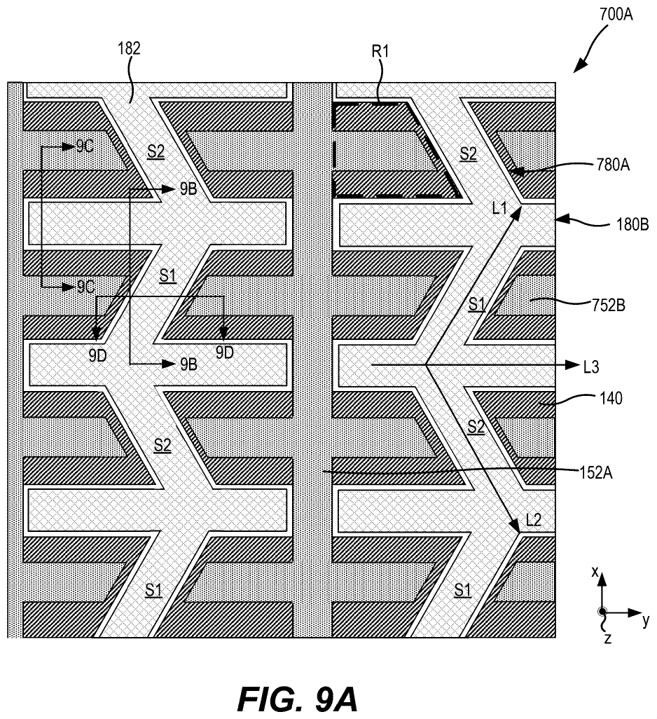

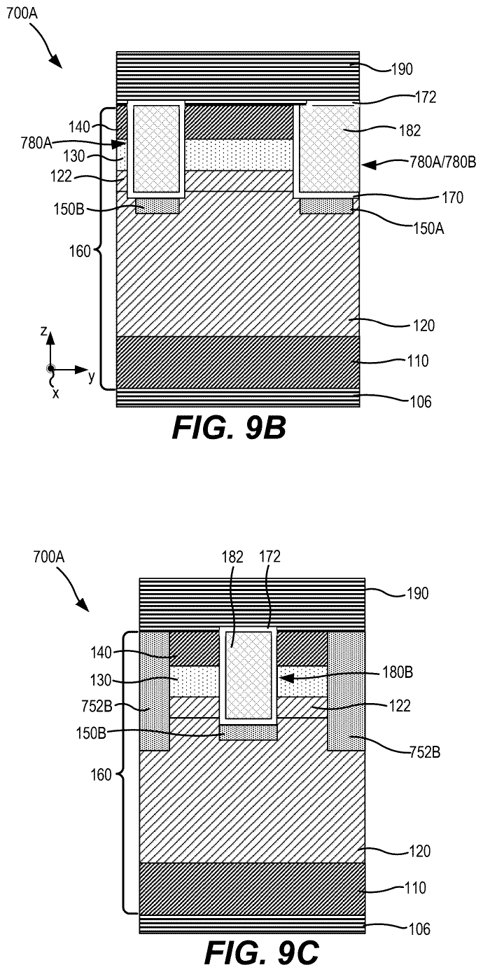

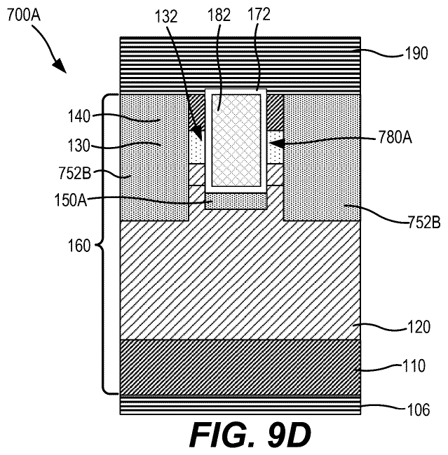

FIG. 9A is a schematic top view of a power MOSFET 700A according to still further embodiments of the present invention that includes gate trenches that have a zig-zag pattern. In FIG. 9A, the upper dielectric layers and the source metallization are omitted to show the gate electrodes and the upper surface of the semiconductor layer structure. FIGS. 9B-9D are cross-sectional views taken along lines 9B-9B, 9C-9C and 9D-9D of FIG. 9A, respectively, with the upper dielectric layers and the source metallization that are omitted in FIG. 9A added for context.

Power MOSFET 700A is similar to power MOSFET 100B of FIG. 3G in that power MOSFET 700A includes a plurality of continuous first gate trenches 780A that generally extend in the x-direction, a plurality of second gate trenches 180B that extend in the y-direction, a plurality of first support shields 152A that extend in the x-direction, and a plurality of second support shields 752B that extend in the y-direction. The primary difference between power MOSFET 700A and power MOSFET 100B is that in power MOSFET 700A the gate trenches 780A have a zig-zag shape. Conventionally, gate trench silicon carbide based power MOSFETs are fabricated so that the gate trenches extend only along one crystallographic face of the semiconductor layer structure, where the face is typically the m-face or the a-face. As described above, pursuant to embodiments of the present invention, gate trenches are provided that extend along multiple crystallographic faces of the semiconductor layer structure (e.g., first gate trenches that extend along m-faces and second gate trenches that extend along a-faces). In silicon carbide, equivalent crystallographic faces of the semiconductor layer structure are 60° apart, and hence it is also possible to form gate trenches that have segments that extend at different angles corresponding to different equivalent crystallographic faces of the semiconductor layer structure. Power MOSFET 700A is an example of a semiconductor device that has such a design.

As shown in FIG. 9A, the first gate trenches 780A of power MOSFET 700A extend generally in the x-direction, but have a zig-zag shape when viewed from above. As such, each first gate trench 780A includes a plurality of first segments S1 that have first longitudinal axes L1 and a plurality of second segments S2 that have second longitudinal axes L2. Power MOSFET further includes a plurality of second gate trenches 180B which have third longitudinal axes L3 that extend in the y-direction. The second gate trenches 180B may be similar or identical to the like-numbered second gate trenches 180B of power MOSFET 100B. The first segments S1 and the second segments S2 are laid out in an alternating arrangement to form continuous first gate trenches 780 that each have alternating first and second segments S1, S2.

The first longitudinal axes L1 of the first segments S1 all extend in a (same) first direction in parallel to each other. Likewise the second longitudinal axes L2 of the second segments S2 all extend in a (same) second direction in parallel to each other. The second direction intersects the first direction. In the depicted embodiment, the first longitudinal axis L1 of each first segment S1 intersects the third longitudinal axis L3 of a second gate trench 180B to define an angle of 60° as shown in FIG. 9A. Likewise, the second longitudinal axis L2 of each second segment S2 intersects the third longitudinal axis L3 of a second gate trench 180B to define an angle of 60°. As is also shown in FIG. 9A, the first longitudinal axis L1 of each first segment S1 intersects the second longitudinal axis L2 of an adjacent second segment S2 to define an angle of 120.

As shown in FIG. 9A, a first gate trench 780A, two adjacent second gate trenches 180B, and a first support shield 152A define a trapezoid-shaped region in the semiconductor layer structure that has two right angles (see region R1 in FIG. 9A) when power MOSFET 700A is viewed from above. A plurality of these trapezoid-shaped regions are formed in the semiconductor layer structure 160. As shown in FIG. 9A, three of the four sides of each of these trapezoidal regions R1 may comprise channel region.

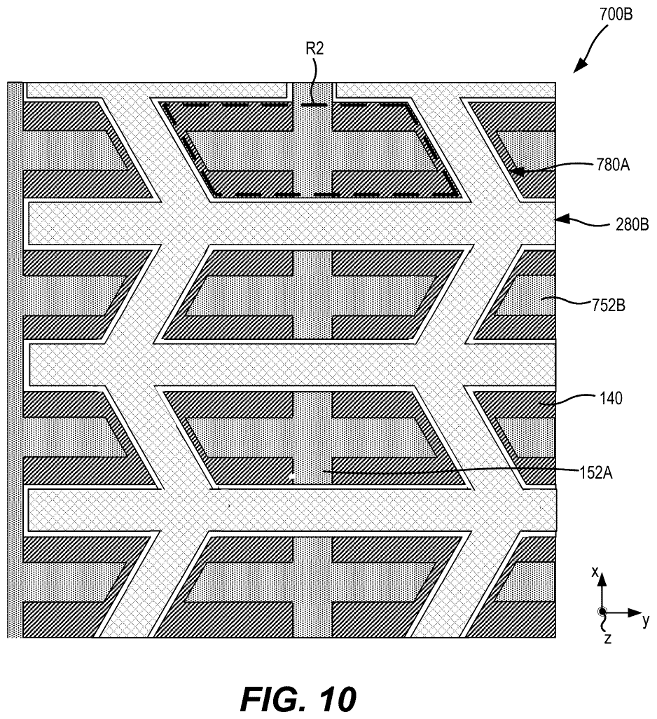

It will be appreciated that FIGS. 9A-9D illustrate one example of a power MOSFET that includes first gate trenches 780A that have a zig-zag shape and second gate trenches 180B that are linear trenches (here linear and discontinuous). Embodiments of the present invention, however, are not limited thereto. In fact, power MOSFET 700A may be modified to have the form of any of the power MOSFETS discussed above with reference to FIGS. 3A-8D, except that the first gate trenches in the power MOSFETs of FIGS. 3A-8D would be replaced with the first gate trenches 780A that have the zig-zag design shown in FIG. 9A. As one such example, FIG. 10 is a schematic top view of a power MOSFET 700B that is a modified version of the power MOSFET 700A of FIGS. 9A-9D. In FIG. 10, the upper dielectric layers and the source metallization of power MOSFET 700B are omitted to show the gate electrodes and the upper surface of the semiconductor layer structure thereof.

As shown in FIG. 10, power MOSFET 700B is very similar to power MOSFET 700A, with the primary difference being that power MOSFET 700B has continuous second gate trenches 280B instead of the discontinuous second gate trenches 180B included in power MOSFET 700A. As a result of this change, the first and second gate trenches 780A, 280B form a continuous gate trench mesh that defines a plurality of mesas in the semiconductor layer structure 160. As shown in FIG. 10, each mesa may be a parallelogram-shaped regions R2 when power MOSFET 700B is viewed in plan view. A portion of a respective one of the first support shields 152A and a portion of a respective one of the second support shields 752B are provided in each parallelogram-shaped mesa and together may form a cross shape when power MOSFET 700B is viewed from above.

Referring to FIGS. 9A-9D and 10, pursuant to further embodiments of the present invention, semiconductor devices are provided such as power MOSFETs 700A, 700B that comprise a semiconductor layer structure 160 that comprises a drift region 120 having a first conductivity type, a plurality of continuous first gate trenches 780A in the semiconductor layer structure 160, and a plurality of second gate trenches 180B, 280B in the semiconductor layer structure 160, where the second gate trenches 180B, 280B intersect the first gate trenches 780A. The first gate trenches 780A are formed in an upper surface of the semiconductor layer structure 160, and each first gate trench 780A has a zig-zag shape when viewed from above. The semiconductor layer structure 160 further comprises a plurality of first support shields 152A that have the second conductivity type.

In power MOSFET 700A (FIGS. 9A-9D), the first and second gate trenches 780A, 180B and the first support shields 152A define a plurality of trapezoid-shaped regions R1 in the semiconductor layer structure 160, where each trapezoid-shaped region R1 has two right angles. In power MOSFET 700B (FIG. 10), the first and second gate trenches 780A, 280B define a plurality of parallelogram-shaped mesa regions R2 in the semiconductor layer structure 160.

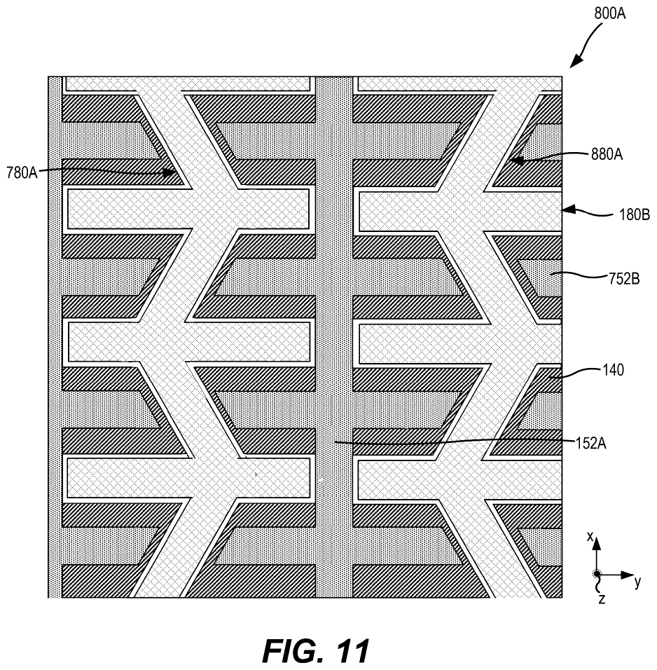

FIG. 11 is a schematic top view of a power MOSFET 800A according to still further embodiments of the present invention that has gate trenches that follow a different zig-zag pattern. In FIG. 11, the upper dielectric layers and the source metallization are omitted to show the gate electrodes and the upper surface of the semiconductor layer structure.

As can be seen by comparing FIGS. 9A and 11, power MOSFET 800A differs from power MOSFET 700A in that power MOSFET 800A includes two different types of first gate trenches, namely first gate trenches 780A that are identical to the like-numbered first gate trenches 780A of power MOSFET 700A, and first gate trenches 880A that are offset in the x-direction by one segment from the first gate trenches 780A so that the first gate trenches 780A and the first gate trenches 880A zig-zag in opposite directions. As power MOSFET 800A may otherwise be identical to power MOSFET 700A, further description thereof will be omitted here.

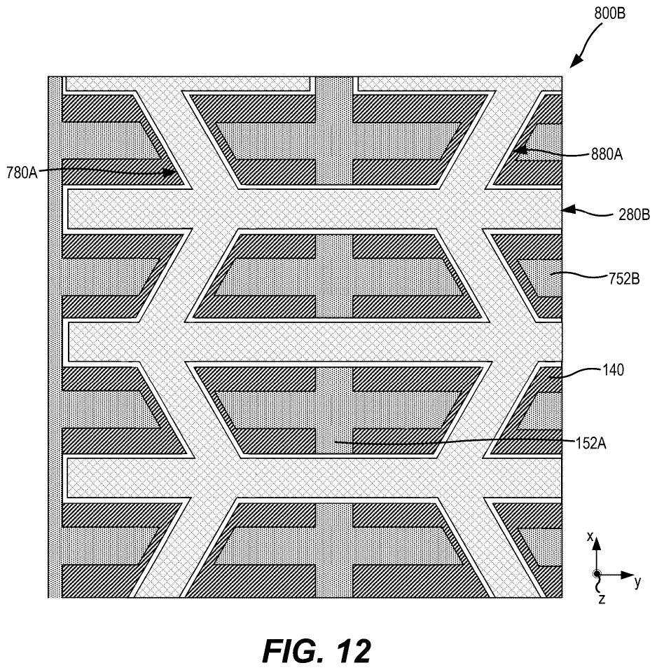

FIG. 12 is a schematic top view of a power MOSFET 800B that is a modified version of the power MOSFET 800A of FIG. 11 with the upper dielectric layers and the source metallization omitted to show the gate electrodes and the upper surface of the semiconductor layer structure. As shown in FIG. 12, power MOSFET 800B is very similar to power MOSFET 800A, with the primary difference being that power MOSFET 800B has continuous second gate trenches 280B instead of the discontinuous second gate trenches 180B included in power MOSFET 800A. As a result of this change, the first and second gate trenches 880A, 280B form a continuous gate trench mesh that defines a plurality of mesas in the semiconductor layer structure 160. As shown in FIG. 12, each mesa may have an isosceles trapezoid-shape when power MOSFET 800B is viewed in plan view. A portion of a respective one of the first support shields 152A and a portion of a respective one of the second support shields 752B are provided in each isosceles trapezoid-shaped mesa and together may form a cross shape when power MOSFET 800B is viewed from above.

Referring to FIGS. 9A-12, pursuant to further embodiments of the present invention, semiconductor devices are provided such as power MOSFETs 700A, 700B, 800A, 800B that comprise a semiconductor layer structure 160 that comprises a drift region 120 having a first conductivity type, a first gate trench 780A, 880A in the semiconductor layer structure 160 that has alternating first segments S1 and second segments S2, where first longitudinal axes L1 of the first segments S1 each extend in a first direction and second longitudinal axes L2 of the second segments S2 each extend in a second direction that intersects the first direction. These devices further include a second gate trench 180B, 280B in the semiconductor layer structure 160 that intersects the first gate trench 780A, 880A.

The second gate trench 180B, 280B may intersect the first gate trench 780A, 880A at a location where one of the first segments S1 merges into one of the second segments S2. The second gate trench 180B, 280B may extend along a third longitudinal axis L3, and the first longitudinal axis L1 of a first of the first segments S1 and the third longitudinal axis L3 may define a first angle A1, and the second longitudinal axis 12 of a first of the second segments S2 and the third longitudinal axis L3 may define a second angle A2, where the second angle A2 has the same absolute value as the first angle A1. The first gate trench 780A, 880A has a zig-zag shape when viewed from above. A first support shield 152A may also be formed in the semiconductor layer structure 160. The first support shield 152A may have a second conductivity type and may extend along a fourth longitudinal axis that extends in parallel to the third longitudinal axis L3.

Still referring to FIGS. 9A-12, pursuant to additional embodiments of the present invention, semiconductor devices are provided such as power MOSFETs 700A, 700B, 800A, 800B that comprise a semiconductor layer structure 160 that comprises a drift region 120 having a first conductivity type, a first gate trench 180B, 280B in the semiconductor layer structure 160 that has a first longitudinal axis L1 that extends in a first direction, and a second gate trench 780A, 880A in the semiconductor layer structure 160 that has a zig-zag shape when viewed from above. The power MOSFET may further comprise a third gate trench 780A, 880A in the semiconductor layer structure that also has a zig-zag shape when viewed from above.

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above.

References are made herein to a first element extending deeper into a semiconductor layer structure of a gate trench semiconductor device than a second element. The depth that an element extends into a semiconductor layer structure refers to a distance that the element extends from an upper surface of the semiconductor layer structure, where the upper surface is the surface from which the gate trenches extend into the semiconductor layer structure. Thus, if a first element extends deeper into a semiconductor layer structure than a second element, this means that a lowermost surface of the first element is farther from the upper surface of the semiconductor layer structure than is a lowermost surface of the second element. In the embodiments discussed above, the depth is the distance in the z-direction from the uppermost surface of the semiconductor layer structure.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10% unless otherwise indicated.

As used herein, two elements of a semiconductor device are considered to “vertically overlap” if an axis that is perpendicular to the major surfaces of a semiconductor layer structure of the semiconductor device intersects both elements.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes,” “including” and “having” when used herein, specify the presence of stated features, elements, and/or components, but do not preclude the presence or addition of one or more other features, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a flow chart. It will be appreciated that the steps shown in the flow chart need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device, comprising:
a semiconductor layer structure comprising a drift region having a first conductivity type;
a plurality of continuous first gate trenches in the semiconductor layer structure; and
a plurality of second gate trenches in the semiconductor layer structure, the second gate trenches intersecting the first gate trenches.

2. (canceled)

3. The semiconductor device of claim 1, wherein the first gate trenches extend in parallel to each other and each first gate trench has a longitudinal axis that extends in a first direction.

4. The semiconductor device of claim 3, wherein the first gate trenches and the second gate trenches are in an upper surface of the semiconductor layer structure, and each first gate trench has a zig-zag shape when viewed from above.

5. The semiconductor device of claim 4, wherein the first and second gate trenches define a plurality of parallelogram-shaped mesas in the semiconductor layer structure.

6. The semiconductor device of claim 4, wherein the first and second gate trenches define a plurality of isosceles trapezoid-shaped regions in the semiconductor layer structure.

7. The semiconductor device of claim 4, wherein the semiconductor layer structure further comprises a plurality of first support shields that have the second conductivity type, the first support shields having respective third longitudinal axes that extend in the first direction in parallel to each other.

8. The semiconductor device of claim 7, wherein the first gate trenches, the second gate trenches and the first support shields together define a plurality of trapezoid-shaped regions in the semiconductor layer structure, where each trapezoid-shaped region has two right angles.

9. The semiconductor device of claim 3, wherein the semiconductor layer structure further comprises a plurality of first support shields that have the second conductivity type, the first support shields having respective third longitudinal axes that extend in the first direction in parallel to each other.

10. The semiconductor device of claim 9, wherein the second gate trenches each have respective longitudinal axes that extend in a second direction in parallel to each other, where the second direction is different from the first direction.

11. The semiconductor device of claim 10, wherein the second direction is perpendicular to the first direction.

12. The semiconductor device of claim 11, wherein the semiconductor layer structure further comprises a plurality of second support shields that have the second conductivity type, the second support shields having respective fourth longitudinal axes that extend in the second direction in parallel to each other.

13. The semiconductor device of claim 12, wherein the second gate trenches are discontinuous gate trenches that each comprise a plurality of colinear spaced apart segments.

14-23. (canceled)

24. A semiconductor device, comprising:
a semiconductor layer structure comprising a drift region having a first conductivity type;
a plurality of parallel first gate trenches in the semiconductor layer structure that have respective first longitudinal axes that extend in a first direction;
a plurality of parallel second gate trenches in the semiconductor layer structure that have respective second longitudinal axes that extend in a second direction that intersects the first direction;
a plurality of parallel first support shields that have the second conductivity type in the semiconductor layer structure that have respective third longitudinal axes that extend in the first direction; and
a plurality of parallel second support shields that have the second conductivity type in the semiconductor layer structure that have respective fourth longitudinal axes that extend in the second direction.

25. The semiconductor device of claim 24, wherein the first gate trenches are continuous gate trenches and the second gate trenches are discontinuous gate trenches.

26. The semiconductor device of claim 25, wherein the first support shields are continuous support shields and the second support shields are discontinuous support shields.

27. The semiconductor device of claim 24, wherein the first support shields are continuous support shields and the second support shields are discontinuous support shields.

28. The semiconductor device of claim 24, wherein the first gate trenches are discontinuous gate trenches and the second gate trenches are discontinuous gate trenches.

29. The semiconductor device of claim 28, wherein each segment of the discontinuous first gate trenches intersects a respective segment of the discontinuous second gate trenches to form a plurality if cross-shaped gate trench sections when the semiconductor device is viewed from above.

30. The semiconductor device of claim 29, wherein the first gate trenches are continuous gate trenches and the second gate trenches are continuous gate trenches.

31. The semiconductor device of claim 30, wherein the first support shields are continuous support shields.

32-49. (canceled)

50. A semiconductor device, comprising:
a semiconductor layer structure comprising a drift region having a first conductivity type;
a plurality of parallel first gate trenches in the semiconductor layer structure that have respective first longitudinal axes that extend in a first direction;
a plurality of parallel second gate trenches in the semiconductor layer structure that have respective second longitudinal axes that extend in a second direction that is perpendicular to the first direction so that the first gate trenches and the second gate trenches form a gate trench mesh that defines a plurality of mesas in the semiconductor layer structure; and
a plurality of first support shields in the semiconductor layer structure that have the second conductivity type.

51. The semiconductor device of claim 50, wherein support shields are at least partially within the mesas.

52. The semiconductor device of claim 50, wherein the gate trench mesh is a continuous gate trench mesh.

53. The semiconductor device of claim 52, wherein each first support shield comprises a continuous first support shield.

54. The semiconductor device of claim 53, further comprising a plurality of second support shields in the semiconductor layer structure that have the second conductivity type.

55-80. (canceled)
